(19) United States
(12) Patent Application Publication
(10) Pub. No.: US 2026/0154464 A1
(43) Pub. Date: Jun. 4, 2026

(54) SYSTEMS AND METHOD FOR OPTIMIZING INDUSTRIALIZED CONSTRUCTION CAPACITIES OF A BUILDING STRUCTURE

(71) Applicant: GLOBAL BAMBOO TECHNOLOGIES INC., Windsor, CA (US)

(72) Inventors: William H. Hinkle, Geyserville, CA (US); Nicholas T. Allan, Santa Rosa, CA (US)

(73) Assignee: GLOBAL BAMBOO TECHNOLOGIES INC., Windsor, CA (US)

(21) Appl. No.: 19/104,031

(22) PCT Filed: Aug. 18, 2023
(86) PCT No.: PCT/US2023/072490

§ 371 Date: Feb. 14, 2025

Related U.S. Application Data
(60) Provisional application No. 63/371,924, filed on Aug. 19, 2022.

(51) Int. Cl. G06F 30/13

(52) U.S. Cl. CPC G06F 30/13

(57) ABSTRACT

In some aspects, the techniques described herein relate to a method for optimizing industrialized construction capacities of a building structure, including: receiving, by at least one of a design computing device and an optimization computing device, framing design input information including at least one parameter for at least one structural component; processing, by at least one of the design computing device and the optimization computing device, the framing design input information to identify the at least one parameter; and designating, by the optimization computing device, at least one type of material for the at least one structural component based on a correlation between at least one property of the type of material and the at least one parameter of the at least one structural component.

### BACKGROUND

Traditional wood-based low-rise building techniques typically include the use of dimensional lumber, sheeting, beams, trusses, engineered lumber products, and other components fashioned from wood in the form of lumber or laminated elements. Consequently, the demand for traditionally used framing timber is high, requiring harvesting rates often exceeding the replenishment rates. Today builders are starting to recognize the benefits of using fast-growing structural fibers with superior mechanical properties (e.g., compressive strength, stiffness, etc.) and the ability to quickly sequester carbon.

Timber bamboo—a grass—is one fast-growing fiber that grows in many parts of the world and is starting to be used as a construction material in replace of wood for certain building components and applications. Similarly, Eucalyptus and other fast-growing wood species, which have generally not been used in construction, but which possess superior mechanical properties, high carbon sequestration and sustainability, are also starting to replace traditional framing wood for certain building components and applications. In addition, other bio-based materials are now being processed for inclusion within structural frames of buildings. Here, those structural building fibers with identified biogenic carbon content are termed broadly as “biogenic fibers” or “biogenic structural fibers”.

Because of the high cost of constructing traditional wood frame buildings, prefabricated building panel structures are also being used to significantly save on-site building time. Commonly such structures include some type of wall components or modules which can be manufactured in an off-site plant and joined together on construction sites. Structural building panels have various applications, such as exterior and interior walls, partition walls, floors, roofs, and foundation systems.

Many prefabricated building panel structures are made from combinations of wood, steel, foam, concrete, and/or composite materials. Biogenic structural building panels and other framing components have been developed to take advantage of the compression strength, rapid growth, and high carbon sequestration and sustainability, such as compared to building panels and components made from wood, steel, concrete, synthetic foams, composites, and the like.

### SUMMARY

In some aspects, the techniques described herein relate to a method for optimizing industrialized construction capacities of a building structure, including: receiving, by at least one of a design computing device and an optimization computing device, framing design input information including at least one parameter for at least one structural component; processing, by at least one of the design computing device and the optimization computing device, the framing design input information to identify the at least one parameter; and designating, by the optimization computing device, at least one type of material for the at least one structural component based on a correlation between at least one property of the type of material and the at least one parameter of the at least one structural component.

In some aspects, the techniques described herein relate to a system for optimizing industrialized construction capacities of a building structure, the system including: a computing device having at least one processor and a non-transitory computer-readable medium; wherein the non-transitory computer-readable medium has a data store and computer-executable instructions stored thereon; and wherein the instructions, in response to execution by the at least one processor, cause the computing device to perform actions including: receiving, by the computing device, framing design input information including at least one parameter for at least one structural component; processing, by the computing device, the framing design input information to identify the at least one parameter; and designating, by the computing device, at least one type of material for the at least one structural component based on a correlation between at least one property of the material and the at least one parameter of the at least one-structural component.

In some aspects, the techniques described herein relate to a method of training a machine learning model to optimize industrialized construction capacities of a building structure, the method including: receiving, by an optimization computing device, a first set of training data including at least one parameter for a first structural component for a building structure and a designation of at least one type of material for the first structural component based on a correlation between at least one property of the material and the at least one parameter of the first structural component; adding, by the optimization computing device, the first set of training data in a training data store; and training, by the optimization computing device, the machine learning model to designate at least one type of material for at least one structural component using information stored in the training data store.

In some aspects, the techniques described herein relate to a method of using a machine learning model to optimize industrialized construction capacities of a building structure, the method including: receiving, by a computing device, framing design input information including at least one parameter for at least one structural component of a building structure; processing, by the computing device, the at least one parameter as input using a machine learning model to designate at least one type of material for the at least one structural component; and presenting, by the computing device, at least one type of material for the at least one structural component.

In some aspects, the techniques described herein relate to a method for optimizing industrialized construction capacities of a building structure, including: receiving, by at least one of a design computing device and an optimization computing device, framing design input information including at least one parameter for at least one structural component; processing, by at least one of the design computing device and the optimization computing device, the framing design input information to identify the at least one parameter; and designating, by the optimization computing device, at least one type of material for the at least one structural component based on a correlation between at least one property of the material and the at least one parameter of the at least one structural component; custom fabricating, by a fabrication computing system, the at least one type of material to define the at least one structural component of the at least one type of material; and adding at least one indicia to the at least one structural component of the at least one type of material to indicate at least one of a material name, an optimization rating, and installation instructions.

In some aspects, the techniques described herein relate to a method for optimizing construction capacities of a building structure using prefabricated structural panels, including: receiving, with a computing device, framing design input information including wall cavity access requirements for at least one wall formed with at least one prefabricated structural panel; processing, with a computing device, the framing design input information to determine at least one load requirement for the at least one wall; and designating, by a computing device, at least one of a wall cavity access location for the at least one wall and a header assembly configuration based on structural load requirements for the at least one wall.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative examples, in which the principles of the invention are utilized, and the accompanying drawings, wherein:

FIG. 1 is a schematic illustration of a non-limiting example of an optimization industrialized construction system according to various aspects of the present disclosure.

FIG. 2 is a block diagram that illustrates aspects of a non-limiting example of a design computing device according to various aspects of the present disclosure.

FIG. 3 is a block diagram that illustrates aspects of a non-limiting example of an optimization computing device according to various aspects of the present disclosure.

FIG. 4 is a flowchart that illustrates a non-limiting example of a method of optimizing an industrialized construction system having a least one structural component according to various aspects of the present disclosure.

FIG. 5 is a flowchart that illustrates a non-limiting example of a method of training a machine learning model to optimize an industrialized construction system according to various aspects of the present disclosure.

FIG. 6 is a flowchart that illustrates a non-limiting example of a method of using a machine learning model to optimize an industrialized construction system according to various aspects of the present disclosure.

FIG. 7 is a block diagram that illustrates a non-limiting example of a computing device appropriate for use as a computing device with examples of the present disclosure.

### DETAILED DESCRIPTION

Systems and methods disclosed herein are directed to optimizing an industrialized construction system having a least one structural component, including optimizing at least one of the load, thermal, environmental capacities (e.g., embodied carbon/energy and/or carbon sink), costs, etc. of the at least one structural component. In some examples, the industrialized construction system uses biogenic materials, and optimization includes selecting at least one type of biogenic material for at least one of the structural components of an assembly. The type of biogenic building materials may include any nature-based materials that can vary according to structural (load) capacity, thermal or insulative rating, construction costs (e.g., materials and labor), and operating costs, embodied energy and carbon properties (e.g., carbon footprint and carbon sink), or other properties that may vary and affect the performance and/or the cost of the framing structure (e.g., acoustic performance, mold growth index, water vapor permeance, flame spread (fire safety), ballistic resistance, etc.). For instance, the type of biogenic building materials may include stress-rated or non-stress rated lumber made from various wood or grass species (e.g., bamboo).

It should be appreciated that while the system and methods disclosed herein may include optimizing an industrialized construction system having a least one structural component by designating a type of biogenic material for the component(s), other types of materials (e.g., steel, concrete, composites, etc.) are also within the scope of the present disclosure. Accordingly, when the phrase “biogenic material”, “type of biogenic material”, “material”, or the like is used to describe aspects of the system and method, it should be understood that materials other than biogenic materials may also be used or included.

Current systems and methods for framing a building do not optimize the structural (load) capacity, thermal capacity, embodied energy and carbon properties, cost, or other properties of the materials used to construct the frame.

Regarding optimization of the structural (load) capacity, the structural envelope of a building is comprised of multiple different load path requirements specified mainly by building codes and engineering standards. Those load path requirements are satisfied by the load bearing properties of the principal materials used in the structural building components of the frame and the connections between them. Within any building, a variety of materials and connections can be used to carry or handle the load. Often the specific structural building components chosen result in a material, design, and/or connection that supports a higher load capacity than is required. This can occur because (a) the designer does not have material/component costs relative to performance metrics readily in hand when designing the building, and/or (b) because load requirements can change many times around the perimeter of a structural envelope and it is not time efficient for the structural designer to optimize against 5-50% differences in capacity, despite potential cost savings.

Moreover, industry practice of delivering large amounts of bundled materials to a job site, where the materials have not been discretely individualized with location markings, would largely defeat the efficiencies gained by optimizing the structural design. This is particularly true in the case of biogenic or nature-based materials. A spec sheet may identify the size and/or grade of materials to be used for various applications in the building. For instance, a spec sheet may designate a higher grade of lumber for headers, joists, beams, studs, or posts. However, the spec sheet is typically a piece of paper delivered to a job site, and a contractor must be able to understand and track where the various grades of materials should be used. Although it may be manageable to track and correctly use the lower volume components like headers, joists, and beams, managing various grades of studs, posts, or other high volume framing components on a job site is prone to error. If the multiple grades of material look similarly on the jobsite, it is probable that builders will use the wrong grade of material in the wrong location with troubling frequency.

As a specific example, a post or stud can end up in an area or point location of building having accumulated higher loads (e.g., from built up beams), such as at lower floors of the building. As such, a higher grade of lumber could be designated for posts or studs to support the accumulated loads. However, even if a higher grade of lumber is identified for such posts and studs, the same grade of lumber is generally used throughout in order to avoid the complications and errors noted above. More specifically, instead of using a higher grade of lumber to support a higher load, framers often solve the load issue by adding more framing material of the same type to the post or stud, such as by placing multiple studs/posts side by side. In this manner, various grades of studs and posts do not need to be manually managed.

Increased framing material adds to the overall material and labor costs of the framing. Further, increased framing material increases the overall carbon footprint of the framing structure. In other words, the more material that is harvested, processed, transported, and used, the higher the carbon footprint or embodied carbon of the structure. Increased framing material also decreases the insulative properties of the framing structure. For instance, the thermal break between the inner and outer wall faces is compromised. Moreover, the volume taken up by the additional framing material displaces the volume of using more insulative material in the cavity.

Regarding thermal optimization, different jurisdictions also impose different minimum thermal performance requirements according to codes or other regulations. Owners/developers may set their thermal resistance objectives (R) for a building at the minimum required by the code or at a margin above the code to lower building operating costs. Different materials have differing thermal performance characteristics that are considered during design of the structural frames of buildings. In addition, the materials with same or differing thermal performance will frequently have differing upfront purchase costs, installation costs, operating costs, and operating and embodied carbon. Often thermal design decisions are broad and will materially direct the type of materials that can be used. Moreover, selecting one thermal performance level for one group of materials, e.g., glazing/windows, can have a consequential impact on what other materials (e.g., walls) can be chosen. The overall thermal objectives are often revisited multiple times in the design process.

Regarding cost optimization, higher performing materials can increase the upfront construction costs (e.g., material and labor costs), whereas operating costs over the service life of the material may be lower. Operating costs are typically based on known, current values such that all-in (construction and operating) cost optimization may be performed during the design process (based on input parameters). Construction cost optimization can be balanced with satisfaction of at least minimum structural parameters but is often difficult to optimize while considering other parameters such as carbon footprint.

Similar issues exist with industrialized construction techniques that use prefabricated building panel framing systems. Prefabricated building panels, structural sections, and framing components can be made from various combinations of materials that affect load capacity, thermal performance, embodied carbon, costs, and other properties. As a non-limiting example, biogenic fiber materials like bamboo or other vegetable cane or grasses (hereinafter simply “bamboo”) may be combined with a non-bamboo structural layer to construct a panel, section, or component to vary the load capacity, thermal performance, embodied carbon, and cost.

As an example of combining various fibers within a single component, “non-bamboo structural layer” refers to structural layers or lamina not containing bamboo fibers therein. Representative non-bamboo structural layers include parallel strand lumber (PSL), laminated veneer lumber (LVL), oriented strand board (OSB), laminated strand lumber (LSL), medium density fiberboard (MDF), plywood, chipboard, lumber veneer, dimensional lumber (e.g., at least partially formed of a wood species selected from the group consisting of: spruce pine fir, southern yellow pine, Douglas fir, or whitewood), and the like.

The load capacity of a non-bamboo structural layer can of course vary according to its mechanical properties. Moreover, each bamboo layer can be made from one or more species having various mechanical properties. As an example, bamboo species Dendrocalamus asper (Asper) has an average bending modulus of elasticity (MOE) above 3.2×10⁶ psi, whereas bamboo species Dendrocalamus barbatus (Luong) has an MOE of about 2.1×10⁶ psi, and whereas a wood species Eucalyptus dunnii has an MOE of about 1.9×10⁶ psi. Accordingly, the load capacity of a prefabricated building panel, structural section, or component is defined at least in part by the materials used to fabricate the panel.

The load capacity of a prefabricated building panel or component is also dependent on the design of the panel or component. For instance, the fiber orientation of biogenic materials, the method of joining the layers, the thickness of the layers, use of filler material, etc., can significantly affect panel/component load capacity and possibly its thermal performance. Accordingly, each prefabricated building panel, structural section, or framing component can vary in its optimized load and thermal applications.

The embodied carbon, thermal performance levels, costs, and other properties (acoustic performance, mold growth index, water vapor permeance, flame spread (fire safety), ballistic resistance, etc.) of a prefabricated building panel or component is also dependent on the materials and/or the design of the panel or component. For instance, a first panel made from a combination of bamboo and a wood species having a first thickness will have a higher embodied carbon than a second panel made from a combination of bamboo and a wood species having a second thickness less than the first thickness. In that regard, the first panel may have a higher load capacity, but coupled with a higher embodied carbon, it may be beneficial to use the first panel (rather than the second panel) only when needed to support required loads.

Various prefabricated hybrid biogenic building panel structures and structural sections are described in WO2022026898A1, entitled “Bamboo-hybrid structural panels and structural sections,” hereby incorporated by reference in its entirety.

One known bamboo hybrid structural panel, referred to herein as the “2.0 panel” or “Gen. 2 panel” includes four bamboo structural layers (i.e., along a neutral plane and without any non-bamboo structural layers therebetween) sandwiched between two layers of wood veneer—one on each face. Two of the bamboo structural layers have a vertical grain orientation, while the other two middle bamboo structural layers have an approximate 5-degree skew from vertical.

Another known bamboo hybrid structural panel, referred to herein as the “3.0 panel” or “Gen. 3 panel” may include a plurality of structural layers adhered together in a laminate, including a plurality of bamboo structural layers and at least one non-bamboo structural layer disposed between a first bamboo structural layer and a second bamboo structural layer of the plurality of bamboo structural layers. The first bamboo structural layer and the second bamboo structural layer of the plurality of bamboo structural layers are spaced apart by the at least one non-bamboo structural layer on opposite sides of a neutral plane extending through a center of the structural panel and parallel to the plurality of bamboo structural layers.

Another bamboo hybrid structural panel may be formed at least in part from a bamboo panel element described in U.S. Pat. No. 8,173,236B1, entitled “Bamboo load bearing panel and method of manufacturing”, the disclosure of which is incorporated by reference in its entirety. For instance, a bamboo panel element may include a bamboo laminate layer with first and second layers formed of a plurality of bamboo strips, each having a cortex and a pith surface, longitudinally cut from bamboo culm and pressed flat, wherein each of the bamboo strips within the first and second layers are arranged parallel to one another with the cortex surfaces facing the same direction within a layer and the bamboo strips within the first layer are oriented alike and opposite the bamboo strips within the second layer such that an internal interface between the first and second layers is formed by bonded together the corresponding cortex surfaces of the bamboo strips in the first and second layers and first and second outer surfaces of the bamboo laminate layer are defined by the pith surfaces of bamboo strips respectively in the first and second layers.

In another instance, the bamboo panel element may include a laminate layer with first and second layers formed of a plurality of bamboo strips, wherein the bamboo strips have cortex and pith surfaces, are parallel and are longitudinally cut from bamboo culm, pressed flat and planed, wherein the cortex surfaces of the bamboo strips in the first layer, having the cortex surfaces oriented alike, are bonded to the cortex surfaces of the bamboo strips in the second layer, and a wood veneer layer bonded to the pith surfaces of the bamboo strips in the first layer, wherein the wood veneer layer is positioned such that grain of the wood veneer layer is perpendicular to grain of the bamboo strips.'

Another bamboo hybrid structural panel is described in U.S. patent Ser. No. 10/195,821B1, entitled “Bamboo laminated construction panel and method of manufacture”, the disclosure of which is incorporated by reference in its entirety. For instance, a bamboo laminated construction panel may include at least two layers of prepared bamboo laminated together with outside surface wood veneer layers. Linear bamboo starter boards, made from timber bamboo culm cut to length, split longitudinally, processed to remove sugars, pressed flat into bamboo planks with the soft pith surfaces of two bamboo planks laminated together with grain aligned, may be disposed adjacent to each other along the longitudinal side edges forming a linear bamboo starter board layer. The bamboo laminated panel may be formed by laminating a first wood veneer layer with grain disposed perpendicular to the vertical centerline of the finished panel, first and second bamboo starter board layers with grains aligned opposingly and equally offset from the centerline, and a second wood veneer layer with grain also perpendicularly aligned. Additional bamboo starter board layers are optionally included in pairs to form thicker panels.

Another bamboo hybrid structural panel is described in U.S. patent Ser. No. 11/175,116B2, entitled “Bamboo and/or vegetable cane fiber ballistic impact panel and process”, the disclosure of which is incorporated by reference in its entirety. For instance, a ballistic panel may include a plurality of vegetable cane fibers (e.g., bamboo fibers) impregnated with a polymer. The vegetable cane fibers may be formed into mats of interconnected and entangled fibers and the polymer may be formed into polymer films. The polymer films and mats may be arranged into a layered assembly having an alternating arrangement and pressed together. The layered assembly may be heated to soften the polymer and allow it to flow around the vegetable cane fibers to impregnate the vegetable cane fibers and then cooled. The vegetable cane fibers may be generally uniformly distributed through the entire thickness of the panel and vegetable cane fibers originally formed within different mats are entangled with each other.

In examples, prefabricated building components may be fabricated from one or more species of bamboo or other biogenic fibers. For instance, a high strength bamboo I-beam is described in U.S. Pat. No. 8,561,373B1, entitled “Bamboo I-beam with laminated web and flanges,” the disclosure of which is incorporated by reference in its entirety. A high strength bamboo I-beam may include a bamboo web formed from bamboo boards formed by splaying, pressing and planing bamboo culm and having flanges laminated to the top and bottom of the web. The I-beam flanges may each include a laminated bamboo flange element on either side of the web portion wherein the top and bottom edges of the web portion are flush with the top and bottom flanges of the I-beam. The flange elements may be formed from laminated strips of splayed, pressed and planed bamboo culm. The I-beam may be bonded with non-formaldehyde adhesives. Orientation of the high fiber cortex regions of the bamboo boards imparts structural characteristics to the beam. Such a bamboo I-beam provides a lightweight, low cost, high strength, and fire-resistant load bearing construction component as compared to traditional lumber fabricated beams.

For ease of use, the prefabricated building panels, sections, and framing components may simply be rated for load capacity based on the lowest grade (i.e., lowest load capacity) of biogenic material used to construct the panels/component. As such, the panel/component will sufficiently withstand load requirements regardless of its location in the framing structure. Various blocking scenarios may also be used to provide additional support for the lower grade panels.

Systems and methods disclosed herein are directed to optimizing the use of industrialized building materials or structural components based on at least one of a load capacity, embodied carbon, operational carbon, thermal performance levels, costs, mechanical, electrical, plumbing, and/or insulation (MEPI) access requirements, or other requirements for a specific location or area in the frame (e.g., load requirements for certain structural members) or overall requirements for the frame (such as building code requirements, building type (e.g., low rise, Type 1 to Type 5, etc.), maximum construction and/or operating costs, thermal resistance objectives (R), maximum embodied carbon for the frame, etc.). The structural components may include general framing components (e.g., studs, joists, beams, headers, trusses, columns, plates, etc.), prefabricated building panel structures (e.g., panels and their connection assemblies, panel sections, wall cavity access panels and any header assemblies used to support the wall cavity access locations, etc.), or other components that can be fabricated at least in part from various materials (such as types of biogenic materials).

Optimization may include designating a certain type of material for a frame member or an area in the frame to optimize the load capacities, embodied carbon, thermal performance levels, and/or cost of the frame member/area. For instance, a first type of prefabricated building panel or structural member having a first load capacity may be used for a first portion of the frame having a first required load (e.g., a wall supporting a beam), whereas a second type of prefabricated building panel or structural member having a second load capacity lower than the first load capacity may be used for a second portion of the frame having a second required load lower than the first required load (e.g., a wall that is located between beams).

The type of prefabricated building panel or structural member may depend on the materials used to construct the panel or structural member or its design/configuration (e.g., biogenic materials v. other materials, the biogenic fiber orientation, stress v. non-stressed, the method of joining the layers, the thickness of the layers, use of filler material, etc.). For instance, a Gen. 3 panel may be used for the first portion of the frame and a Gen. 2 panel may be used for the second portion of the frame.

By using a prefabricated building panel or structural member having a load capacity that corresponds to the required load of the frame, less material may be used to support the necessary load, thereby potentially reducing the cost of labor associated with the framing material, and/or the embodied carbon. In that regard, it should be appreciated that by load optimizing the frame and using less materials to support necessary loads, the system may cost and/or carbon optimize the frame in some instances.

In that regard, optimization may also include designating a certain type of material for a frame member or area in the frame to optimize the environmental capacities of the frame. For instance, a first prefabricated building panel or structural member having a first embodied carbon property may be used for the first portion of the frame having a first required load, and a second prefabricated building panel or structural member having a second load capacity lower than the first load capacity may be used for the second portion of the frame having a second required load lower than the first required load. For instance, if a first material had a higher embodied carbon than the second material, it would be environmentally beneficial to use the first material only where needed to support necessary loads or other requirements (e.g., thermal, acoustic, fire resistance, ballistic, etc.).

Optimization may also include designating a certain type of material for a frame member or area in the frame to optimize the thermal capacities of the frame. For instance, a first prefabricated building panel or structural member having a first thermal performance rating and a first load capacity may be used for a first portion of the frame to support a first thermal level and load requirement (e.g., walls panels to support certain glazing/windows). In other instances, a first prefabricated building panel or structural member having a first thermal performance rating and a first embodied carbon and/or first costs may be used for a building having first thermal resistance objectives (R) at the minimum required by the code, whereas a second prefabricated building panel or structural member having a second thermal performance rating higher than the first thermal performance rating and a second embodied carbon and/or second costs may be used for a building having second thermal resistance objectives (R) at a margin above the code.

Optimization may also include designating a certain type of material for a frame member or area in the frame to optimize the construction and/or operating costs of the frame. For instance, a first prefabricated building panel or structural member having a first upfront and/or operating costs and a first load capacity may be used for a first portion of the frame having a first required load, and a second prefabricated building panel or structural member having a second upfront and/or operating costs lower than the first upfront and/or operating costs and a second load capacity lower than the first load capacity may be used for the second portion of the frame having a second required load lower than the first required load. Costs may be optimized in consideration with other criteria, such as thermal performance requirements and embodied carbon.

Optimization may include using one or more of the prefabricated building panels, sections, and framing components described herein. However, other prefabricated building panels, sections, and framing components, such as bamboo hybrid structural panels and components now known or later developed, are also within the scope of the present disclosure. For instance, bamboo hybrid structural panels and components may be developed to include layers of eucalyptus or other materials that are more sustainable than traditional framing wood. Such panels may be suitable for lower load capacity areas but when used in combination with higher grade panels, contribute to an overall lower embodied carbon and/or costs for the frame. In other instances, bamboo hybrid structural panels and components may be developed to include layers of waste material for lower load capacity areas. Using waste material will lower the embodied carbon of the panel or component (less disposal of materials, no additional transportation costs, and emissions, etc.). Again, when used in combination with higher grade panels, such panels would also contribute to an overall lower embodied carbon and/or costs for the frame. Accordingly, the descriptions provided herein should not be seen as limiting.

Optimization may include designating a header assembly configuration for a building cavity access assembly using prefabricated structural panels. For instance, if wall cavity access (e.g., for MEPI access) is required in an area with a first load requirement below a threshold level of vertical load, a first type of header assembly above a removable wall cavity access panel(s) in the wall may be used. If wall cavity access is required in an area with a second load requirement above the threshold level of vertical load, a second type of header assembly may be used above the removable wall cavity access panel(s). If wall cavity access is required in an area with high shear load requirements, at least one shear load support element (such as a bottom panel or panel portion extending across a bottom of the wall panel gap and/or horizontal straps/structure) may be used.

Moreover, optimization may include designating a cavity access location, such as for a wall, based on structural load requirements for the building when cavity access location for the building is flexible. As can be appreciated, a header assembly above a removable wall cavity access panel(s) in a wall defined by prefabricated structural building panels may not provide the same vertical load support as a full height, on-edge prefabricated structural panel. In that regard, optimization may include designating wall cavity access locations in areas of the building having lower load requirements (e.g., below a threshold level of vertical load), if the wall cavity access has flexibility in its location.

For instance, optimization may incorporate some or all aspects of the systems and methods described in U.S. Provisional Patent Application No. 63/520,459, entitled “Prefabricated Building Structure Systems and Methods for Assembling the Same,” hereby incorporated by reference herein in its entirety.

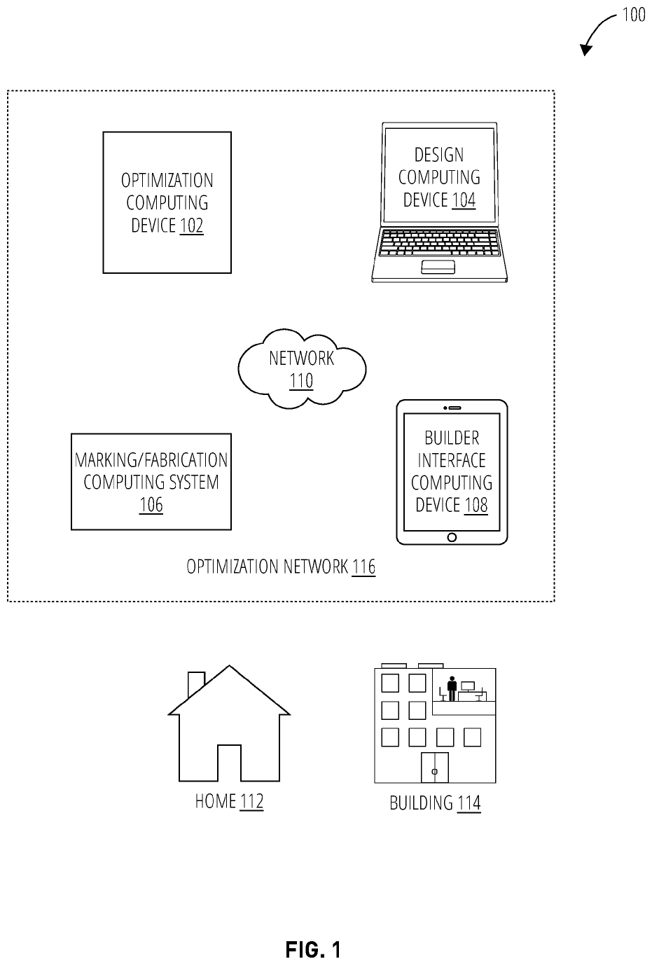

FIG. 1 is a schematic illustration of a non-limiting example of an industrialized construction optimization system 100 according to various aspects of the present disclosure. The industrialized construction optimization system 100 may include various networked computing devices configured for carrying out aspects of an optimization process, such as optimizing the use of biogenic building materials based on load capacity, thermal performance requirements, embodied carbon, costs, or other requirements for a specific location or area in the frame and/or the frame in its entirety (e.g., acoustic, fire resistance, ballistic, etc.).

In the depicted example, the industrialized construction optimization system 100 includes an optimization computing device 102, a design computing device 104, a marking/fabrication computing system 106, and a builder interface computing device 108 communicatively coupled together through a network 110. The network 110 can be any kind of network capable of enabling communication between the various components of the industrialized construction optimization system 100. For example, the network can be a Wi-Fi network.

Generally, the networked components define an optimization network 116 that can be used to optimize one or more stages of a building process of a home 112, a building 114, or the like (hereinafter sometimes simply referred to as a “building”). For instance, one or more networked components in the optimization network 116 may be used to optimize the component design stage, the component assembly stage, and/or the building stage of the process.

In one example, the design computing device 104 is generally used to designate design requirements and/or the layout of the framing of a building and/or any component requirements. For instance, the design computing device 104 may be configured to receive building design information in the form of architectural and/or structural drawings or data, code requirements, etc., and after processing that data (by the user or through other automated platforms), the design computing device 104 may be configured to output building and/or component design requirements for use by the optimization computing device 102 or another computing device.

In that regard, the optimization computing device 102 may be configured to receive and process data from the design computing device 104 for carrying out an optimization process. The optimization process may include designating a certain type of material(s) for a building frame member(s) or an area(s) in the building frame to optimize the capacities of the frame (e.g., load, environmental, thermal, cost, or other capacities). The optimization process may also include designating a header assembly design for a building cavity access assembly in a portion of the building using prefabricated structural panels requiring a cavity access panel(s), and/or the optimization process may include designating cavity access locations based on structural load requirements for the building where cavity access location is flexible. In some examples, the optimization computing device 102 may be configured to send optimization data to the design computing device 104 for carrying out an iterative design/optimization process in parallel with a structural framing design process, such as by presenting various combinations of types of material for different components or portions of the frame that may be received and processed for selection.

In some examples of the present disclosure, one or more machine learning models may be trained to recommend one or more types of material(s) (such as biogenic materials) for certain building and/or component design requirements. In some examples, the machine learning models can be used to determine a type of material(s) for a building frame member or an area in the building frame based on one or more factors of the frame requirements. For example, a user may input load requirements for a frame, and the machine learning model may be run to determine a type of material(s) for a first portion of the frame based on other requirements for at least a second portion of the frame. In some examples, one or more machine learning models may be trained to recommend a header assembly design for a building cavity access assembly in a portion of the building using prefabricated structural panels and/or a preferred cavity access location(s) based on structural load requirements for the building where location of the cavity access is flexible. In some examples, the optimization computing device 102 may be configured to send machine learning model data to the design computing device 104 for carrying out an iterative design/optimization process in parallel with a structural framing design process, such as by presenting various combinations of types of material for different components or portions of the frame that may be received and processed for selection.

In one example, the marking/fabrication computing system 106 is configured to execute machine readable instructions for custom fabricating (such as by CNC cutting) the type of material(s), (e.g., biogenic panels and framing components). The type of material(s) selected by the optimization process may be custom fabricated into the designated panel or component for use in the designated location in the frame. Panels and components for use in prefabricated building panel structures may have a custom design for each frame location (e.g., the panel or component only fits in a specific location). In that regard, the custom fabricated type of material will be compatible only with the designated location, ensuring that the optimized type of material is used in the correct location.

In one example, the marking/fabrication computing system 106 is also configured to execute machine readable instructions for custom printing the type of material. For instance, each type of material may include printed construction indicia that identifies the material, such as by its required location (e.g., by showing a visual representation of its location relative to the other framing members) such that the type of material is used in the designated location. The printed construction indicia may also include any instructions for installation (e.g., a MEPI map, nail pattern, etc.), an optimization rating generated by the optimization computing device 102 (indicating for instance, the load capacity, thermal performance rating, and/or embodied carbon of the panel or framing component, a designation or rating indicating a grade of the panel or framing member, etc.), or other indicators or instructions.

For instance, the marking/fabrication computing system 106 may incorporate some or all aspects of the systems and methods described in U.S. Patent Application Publication No. US2022064952A1, entitled “Automated MEPI Design for Hollow Wall Construction,” hereby incorporated by reference herein in its entirety.

In one example, the builder interface computing device 108 is configured to provide a visual browser interface for contractors, subcontractors, a job site crew, etc., to view any plans, models, 3D construction orders or plans, etc., showing the position of each type of material (i.e., the location for each panel or component). In that regard, accurate bids can be made by contractors/subcontractors knowing specific panel and component configuration. Moreover, in combination with the printed construction indicia on the type of material, the models or 3D constructions plans ensure ease and accuracy of installation of the type of materials by the job site crew.

In some examples, one or more of the design computing device 104, the marking/fabrication computing system 106, and the builder interface computing device 108 may be excluded in the industrialized construction optimization system 100 and/or combined with other computing devices (such as the optimization computing device 102) in the optimization network 116. Moreover, the industrialized construction optimization system 100 may include one or more additional computing devices not shown for carrying out other aspects of a design, bid, and build process and/or an optimization process for framing a building. Accordingly, the descriptions and illustrations provided herein should not be seen as limiting.

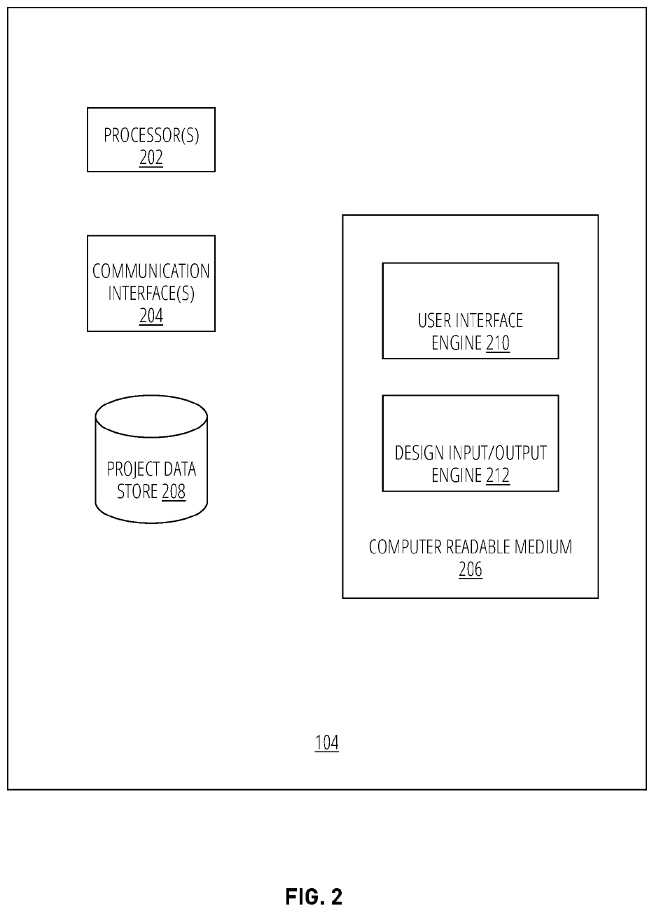

FIG. 2 is a block diagram that illustrates aspects of a non-limiting example of the design computing device 104 according to various aspects of the present disclosure. The illustrated design computing device 104 may be implemented by any computing device or collection of computing devices, including but not limited to a desktop computing device, a laptop computing device, a mobile computing device, a server computing device, a computing device of a cloud computing system, and/or combinations thereof. The design computing device 104 may be configured to receive building design input information from a user and output building design requirements to the optimization computing device 102 for carrying out an optimization process.

As shown, the design computing device 104 includes one or more processors 202, one or more communication interfaces 204, a project data store 208, and computer-readable medium 206.

In some examples, the processors 202 may include any suitable type of general-purpose computer processor. In some examples, the processors 202 may include one or more special-purpose computer processors or AI accelerators optimized for specific computing tasks, including but not limited to graphical processing units (GPUs), vision processing units (VPTs), and tensor processing units (TPUs).

In some examples, the communication interfaces 204 include one or more hardware and or software interfaces suitable for providing communication links between components. The communication interfaces 204 may support one or more wired communication technologies (including but not limited to Ethernet, FireWire, and USB), one or more wireless communication technologies (including but not limited to Wi-Fi, WiMAX, Bluetooth, 2G, 3G, 4G, 5G, and LTE), and/or combinations thereof.

As shown, the computer-readable medium 206 has stored thereon logic that, in response to execution by the one or more processors 202, cause the design computing device 104 to provide a user interface engine 210 and a design input/output engine 212.

As used herein, “computer-readable medium” refers to a removable or nonremovable device that implements any technology capable of storing information in a volatile or non-volatile manner to be read by a processor of a computing device, including but not limited to: a hard drive; a flash memory; a solid state drive; random-access memory (RAM); read-only memory (ROM); a CD-ROM, a DVD, or other disk storage; a magnetic cassette; a magnetic tape; and a magnetic disk storage.

In some examples, the user interface engine 210 is configured to receive framing design input information from a user, such as from at least one of a structural engineer, designer, builder, contractor, etc. The framing design input information may include the structural layout of the building (based on, for instance, an architectural or interior/exterior design), specific load requirements of a framing component(s) (such as based on the structural layout, local code requirements, regulations, intended use of the space, building type (Type 1 to Type 5), etc.), space constraints, thermal resistance objectives (R), overall embodied carbon requirements, construction and/or operating costs restraints, MEPI requirements and/or required (e.g., wall) cavity access locations, etc. In some instances, the user may input load requirements for a specific structural panel or component (e.g., beam, joist, truss, etc.) based on calculations made either manually or with available software programs for determining requirements of a structural member. For instance, the user may indicate that the beams supporting a second floor of a building must have specific structural properties (based on, for instance, the bending moment induced by the load, deflection or deformation caused by the load, horizontal shear at supports, bearing on supporting members, etc.).

In some examples, the design input/output engine 212 is configured to process framing design input information received by the user interface engine 210 and output framing design requirements data to the optimization computing device 102 for carrying out an optimization process. The design input/output engine 212 may extract relevant data from the framing design input information, such as the data specific to load requirements or other requirements needed for carrying out an optimization process. In one aspect, the design input/output engine 212 may receive design input information and extract and package framing design requirements data (such as in Microsoft® Excel format, either automatically or through user interaction) for sending to the optimization computing device 102. In further aspects, the design input/output engine 212 may also receive load optimization model data from the optimization computing device 102 for carrying out an iterative design/optimization process in parallel with a structural framing design process as noted above.

In some examples, aspects of the user interface engine 210 and/or the design input/output engine 212 of the design computing device 104 are integrated into or in communication with building information modeling (BIM) software. BIM is a process including the generation and management of digital representations of physical and functional characteristics of physical spaces. Building Information Models (BIMs) are files (optionally in proprietary formats and containing proprietary data) which can be exchanged or networked to support decision-making. The BIM software may be managed in an open cloud platform (such as a Forge platform) for real-time collaboration between users (e.g., architects, structural engineers, material suppliers, contractors, builders, etc.).

The BIM software may be used to process the framing design input information from a user and generate BIMs of a framing structure, data pertaining to framing requirements (e.g., framing design requirements data), etc. In that regard, the framing design input information may be configured as Revit model data that is transformed by the BIM software into animated 3D construction plans, framing design requirements data, or similar. These models and/or data pertaining to framing requirements may then be extracted and outputted (such as by the design input/output engine 212) to the optimization computing device 102 for carrying out an optimization process.

In other instances, framing structural requirements may be defined by a user (such as a structural engineer) using BIM software or similar, or manually using CAD or hand drawings, and the structural requirements for each of the framing members may be extracted and sent by the user via upload, electronic transfer, etc., to the optimization computing device 102 for carrying out an optimization process.

As shown, the design computing device 104 includes a project data store 208. The project data store 208 may be configured to receive and store framing design input information received by the user interface engine 210 (and/or the BIM software or similar) and/or to receive and store output framing design requirements generated by the design input/output engine 212. In some examples, the project data store 208 may be configured to receive and store optimization data, such as machine learning model data for carrying out an iterative design/optimization process in parallel with a structural framing design process. For instance, the optimization data may be used to present various combinations of types of material for different components or portions of the frame that may be processed for selection by the user interface engine 210. As another example, the optimization data may be used to present various combinations of header configurations and/or (e.g., wall) cavity access locations that may be processed for selection by the user interface engine 210.

As used herein, “data store” refers to any suitable device configured to store data for access by a computing device. One example of a data store is a highly reliable, high-speed relational database management system (DBMS) executing on one or more computing devices and accessible over a high-speed network. Another example of a data store is a key-value store. However, any other suitable storage technique and/or device capable of quickly and reliably providing the stored data in response to queries may be used, and the computing device may be accessible locally instead of over a network, or may be provided as a cloud-based service. A data store may also include data stored in an organized manner on a computer-readable storage medium, such as a hard disk drive, a flash memory, RAM, ROM, or any other type of computer-readable storage medium. One of ordinary skill in the art will recognize that separate data stores described herein may be combined into a single data store, and/or a single data store described herein may be separated into multiple data stores, without departing from the scope of the present disclosure.

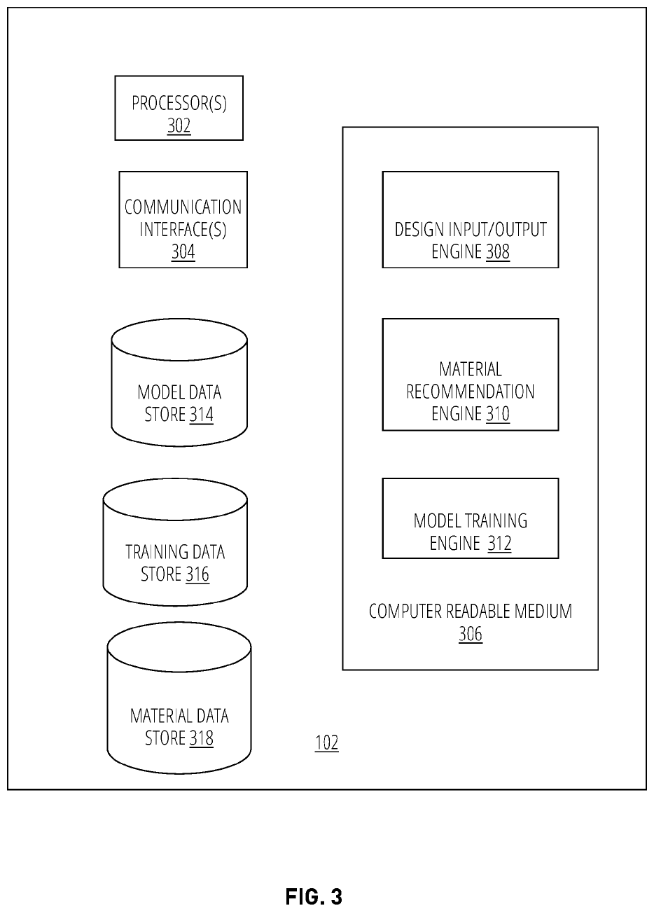

FIG. 3 is a block diagram that illustrates aspects of a non-limiting example of the optimization computing device 102 according to various aspects of the present disclosure. The illustrated optimization computing device 102 may be implemented by any computing device or collection of computing devices, including but not limited to a desktop computing device, a laptop computing device, a mobile computing device, a server computing device, a computing device of a cloud computing system, and/or combinations thereof. The optimization computing device 102 may be configured to receive framing design requirement data from the design computing device 104 and process the data for carrying out an optimization process.

As shown, the optimization computing device 102 includes one or more processors 302, one or more communication interfaces 304, computer-readable medium 306, a design input/output engine 308, a type of material recommendation engine 310, a model training engine 312, a model data store 314, a training data store 316, and a type of material data store 318.

In some examples, the processors 302 may include any suitable type of general-purpose computer processor. In some examples, the processors 302 may include one or more special-purpose computer processors or AI accelerators optimized for specific computing tasks, including but not limited to graphical processing units (GPUs), vision processing units (VPTs), and tensor processing units (TPUs).

In some examples, the communication interfaces 304 include one or more hardware and or software interfaces suitable for providing communication links between components. The communication interfaces 204 may support one or more wired communication technologies (including but not limited to Ethernet, FireWire, and USB), one or more wireless communication technologies (including but not limited to Wi-Fi, WiMAX, Bluetooth, 2G, 3G, 4G, 5G, and LTE), and/or combinations thereof.

As shown, the computer-readable medium 306 has stored thereon logic that, in response to execution by the one or more processors 302, cause the optimization computing device 102 to provide a design input/output engine 308 and a type of material recommendation engine 310.

As used herein, “engine” refers to logic embodied in hardware or software instructions, which can be written in one or more programming languages, including but not limited to C, C++, C#, COBOL, JAVA™, PHP, Perl, HTML, CSS, JavaScript, VBScript, ASPX, Go, and Python. An engine may be compiled into executable programs or written in interpreted programming languages. Software engines may be callable from other engines or from themselves. Generally, the engines described herein refer to logical modules that can be merged with other engines, or can be divided into sub-engines. The engines can be implemented by logic stored in any type of computer-readable medium or computer storage device and be stored on and executed by one or more general purpose computers, thus creating a special purpose computer configured to provide the engine or the functionality thereof. The engines can be implemented by logic programmed into an application-specific integrated circuit (ASIC), a field-programmable gate array (FPGA), or another hardware device.

In some examples, the design input/output engine 308 may be configured to receive framing design requirement data from the design computing device 104 (or from a cloud-based BIM platform or similar). The design input/output engine 308 can process the framing design requirement data by extracting relevant data and/or packaging the data into a suitable form for processing by the type of material recommendation engine 310. For instance, the design input/output engine 308 can extract relevant data from a BIM, an Excel® spreadsheet, or similar, and organize the data into a suitable file format (such as an Excel® spreadsheet) for processing by the type of material recommendation engine 310. As a non-limiting example, the design input/output engine 308 may extract structural data pertaining to the framing members, and specifically, the location of each member in the framing structure, any designated load, thermal performance, embodied carbon, cost requirements, MEPI requirements and/or cavity access location requirements, etc. The design input/output engine 308 may then organize the extracted data, such as by framing member type, load requirement range, thermal performance requirement range, embodied carbon requirement range, cost requirements, framing structure, any designated load, thermal performance, embodied carbon, cost requirements, MEPI requirements and/or cavity access location requirements, etc.

In some examples, the type of material recommendation engine 310 may be configured to receive the processed framing design requirement data from the design input/output engine 308 for carrying out an optimization process. The optimization process may include cross-referencing the processed framing design requirement data for each framing member with property data for types of materials (stored in the type of material data store 318) and designating at least one type of material for each framing member based on at least one property of the type of material.

As a specific example, a beam may be designated as having a specific load (and/or thermal, embodied carbon, or cost) requirement, and the type of material recommendation engine 310 may, based on reference to mechanical or material properties of a categorized list of type of materials, select at least one type of material for the beam. Further, at least one type of material may be selected for one or more other structural components of the assembly based on the requirements of the beam or the overall requirements of the assembly. Various combinations of types of material for the beam and/or the other structural components may be presented.

As another example, a header assembly for a building wall cavity access assembly, as discussed above, may be designated as having a specific load (and/or thermal, embodied carbon, or cost) requirement when the cavity access location is fixed or preferred. As such, the type of material recommendation engine 310 may, based on reference to mechanical or material properties of a categorized list of type of materials, select at least one type of material for the header assembly to support the required load. Further, at least one type of material may be selected for one or more other structural components of the building wall cavity access assembly (e.g., the prefabricated structural panel(s) defining the wall portion having the wall cavity access) based on the requirements of the header assembly or the overall requirements of the building wall cavity access assembly. Various combinations of types of material for the header assembly and/or the other structural components of the building wall cavity access assembly may be presented.

The properties of a type of material may include load capacities (e.g., vertical capacities, transverse capacities, shear capacities, seismic capacities, wind shear capacities, average ultimate vertical load (PLF), any or all of which may be dependent on assembly configuration), thermal performance capacities, fire resistance, environmental capacities (e.g., embodied carbon, net carbon, stored carbon, carbon sink, carbon footprint, etc., hereinafter collectively sometimes referred to as “embodied carbon”) construction and/or costs, or any other properties that may benefit optimization. These various properties may be used to designate an overall grade or rating of the type of material for ease of categorization and designation for structural components requiring certain capacities.

The type of material may include the genus of the material (e.g., biogenic material v. other material, wood v. bamboo, etc.), the species of the material (e.g., softwood v. hardwood, treated v. non-treated lumber, bamboo species X v. bamboo species Y, etc.), the combination of materials (e.g. a hybrid prefabricated building panel structure made from at least two different materials, such as bamboo and wood or other material), component or panel design (such as biogenic fiber orientation, adhesives for joining layers, thickness of the layers, filler/waste materials used, etc.), or any other features that may benefit optimization.

Tables 1 and 2 below show exemplary data representing properties of a type of material, including average ultimate vertical load (PLF), cost of materials in assembly, net carbon, embodied carbon, and stored carbon. The type of materials may include, as shown, prefabricated building panel structures made from primarily three different biogenic materials, Eucalyptus dunnii, Dendrocalamus barbatus, and Dendrocalamus asper. Various fire assembly options for each of the panel structures are included. Exemplary data for each property is identified for each panel option used in a first wall assembly configuration (Table 1) and a second wall assembly configuration (Table 2).

TABLE 1

| | |
|---|---|
| [symbol] | [symbol] |

| [symbol] | [symbol] | [symbol] | [symbol] | [symbol] | [symbol] | [symbol] | [symbol] | [symbol] | [symbol] |
|---|---|---|---|---|---|---|---|---|---|
| [symbol] | [symbol] | [symbol] | [symbol] | [symbol] | [symbol] | [symbol] | [symbol] | [symbol] | [symbol] |
| | | | | [symbol] | [symbol] | [symbol] | [symbol] | [symbol] | [symbol] |
| | | | [symbol] | [symbol] | [symbol] | [symbol] | [symbol] | [symbol] | [symbol] |
| | | | | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] |
| | | | | [symbol] | [symbol] | [symbol] | [symbol] | [symbol] | [symbol] |
| | | | [symbol] | [symbol] | [symbol] | [symbol] | [symbol] | [symbol] | [symbol] |
| | | | | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] |
| | | | | [symbol] | [symbol] | [symbol] | [symbol] | [symbol] | [symbol] |
| | | | [symbol] | [symbol] | [symbol] | [symbol] | [symbol] | [symbol] | [symbol] |
| | | | | [symbol] | [symbol] | [symbol] | [symbol] | [symbol] | [symbol] |

[symbol]

[symbol]

indicates data missing or illegible when filed

TABLE 2

| | | [symbol] | [symbol] | | | | | | |
|---|---|---|---|---|---|---|---|---|---|
| [symbol] | [symbol] | [symbol] | [symbol] | [symbol] | [symbol] | [symbol] | [symbol] | [symbol] | [symbol] |
| [symbol] | 3.1 × | [symbol] .1 × | [symbol] | [symbol] on | 8 [symbol] 05 [symbol] | $ [symbol] . [symbol] | − [symbol] . [symbol] | 0.84 | [symbol] .18 |
| | 10\hat{ } [symbol] | 10\hat{ } [symbol] | | Face and | | | | | |
| | | | | Fiberglass | | | | | |
| | | | | in Core | | | | | |
| | | | [symbol] | [symbol] on | 1752 [symbol] | $ [symbol] . [symbol] 3 | − [symbol] .49 | 0.85 | −4.34 |
| | | | | Face and | | | | | |
| | | | | Fiberglass | | | | | |
| | | | | in Core | | | | | |
| [symbol] | 2.1 × | 3.75 × | [symbol] | [symbol] on | 10,194 | $14.1 [symbol] | −4. [symbol] 0 | 1.70 | [symbol] |
| | 10\hat{ } [symbol] | 10\hat{ } [symbol] | | Face and | | | | | |
| | | | | Fiberglass | | | | | |
| | | | | in Core | | | | | |
| | | | [symbol] | [symbol] on | 18,11 [symbol] | $14.21 | −4.74 | 1.72 | − [symbol] .46 |
| | | | | Face and | | | | | |
| | | | | Fiberglass | | | | | |
| | | | | in Core | | | | | |
| [symbol] | [symbol] .2 × | 4. [symbol] × | [symbol] | [symbol] on | 10721 [symbol] | $14.1 [symbol] | [symbol] . [symbol] 0 | 1.70 | − [symbol] . [symbol] 1 |
| | 10\hat{ } [symbol] | 10\hat{ } [symbol] | | Face and | | | | | |
| | | | | Fiberglass | | | | | |
| | | | | in Core | | | | | |
| | | | [symbol] | [symbol] on | 20516 [symbol] | $14.21 | −4.74 | 1.72 | − [symbol] .4 [symbol] |
| | | | | Face and | | | | | |
| | | | | Fiberglass | | | | | |
| | | | | in Core | | | | | |

[symbol]

indicates data missing or illegible when filed

In some examples, the model training engine 312 is configured to access training data stored in the training data store 316 and to use the training data to generate one or more machine learning models. The model training engine 312 may store the generated machine learning models in the model data store 314. In some examples the type of material recommendation engine 310 is configured to use one or more machine learning models stored in the model data store 314 to process design input information (e.g., framing design requirement data sent from the design input/output engine 308) to designate one or more types of type of material(s) for certain building and/or component design requirements. The models can be used to determine a type of material(s) for a building frame member or an area in the building frame or the entirety of the building frame based on one or more factors of the frame requirements.

In some examples the type of material recommendation engine 310 is configured to use one or more machine learning models stored in the model data store 314 to process design input information to designate design criteria for the one or more types of material(s) such that a panel or structural member may be designed to meet the criteria. For instance, if a wall panel is designated as needing certain load capacities and dimensions, the wall panel may be designated and custom designed (such as with the fabrication computing system 106) to meet the load capacity requirements.

Systems and methods for optimizing an industrialized construction system having a least one structural component, including optimizing at least one of the load, thermal, environmental capacities (e.g., embodied carbon/energy and/or carbon sink), costs, etc., of the at least one structural component are disclosed herein. According to some examples, the method includes designating a certain type of material (such as a type of biogenic material) for a structural component(s) to optimize at least one of the load capacity, thermal performance, environmental (embodied carbon/energy or carbon sink) capacities, and costs of the building structure.

The optimization system and method may include using data inputs that identify values for each structural component or assembly of components. If the input data is per structural component, the assembly options (# of components/assembly) would be included as input so that the optimization method can iterate over the assembly options. The primary inputs (per component and in a set of constrained assembly options) may include:
a) load capacities per various mechanical properties;
b) thermal R (per assembly);
c) embodied carbon (per component, summed by iterated assemblies);
d) construction costs; and
e) operating costs.

The optimization method may solve for lowest construction costs along a (e.g., Pareto) optimal frontier. The model conditions may include:
f) meet or exceed load requirements;
g) for a given thermal performance constraint, meet the minimum thermal requirement or meet a margin above the minimum thermal requirement;
h) provide solution sets at assembly level for f+g;
i) chose a primary objective function from c, d, or e (e.g., d); and
j) show efficient solutions (e.g., types of type of material and/or combinations of the materials) for the primary objective function with subordinate solutions for secondary objectives.

The optimization method may be carried out according to one or more of the methods 400, 500, and 600 described below. Moreover, as noted above, although the methods may be described as designating or selecting at least one type of biogenic material for optimization of the structural component and/or assembly, other types of material may also be appreciated.

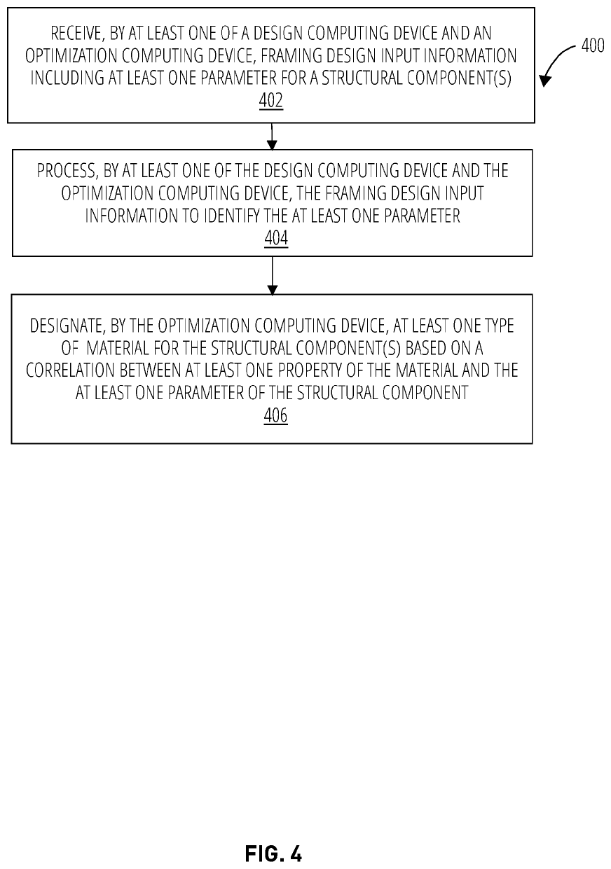

FIG. 4 is a flowchart that illustrates a non-limiting example of a method of optimizing an industrialized construction system having a least one structural component, including optimizing at least one of the load, thermal, environmental capacities (e.g., embodied carbon/energy and/or carbon sink), costs, cavity access locations, etc., of the at least one structural component, according to various aspects of the present disclosure. According to some examples, the method includes designating a certain type of material (such as a type of biogenic material) for a structural component(s) to optimize at least one of the load capacity, thermal performance, environmental (embodied carbon/energy or carbon sink) capacities, costs of the building structure, and cavity access location(s).

At block 402, the method may include receiving, by the design computing device 104, framing design input information including at least one parameter for a structural component (such as a beam, post, joist, header, truss, wall panel, a wall having a building cavity access assembly, etc.). For instance, the user interface engine 210 of the design computing device 104 may receive the framing design input information including at least one parameter for a structural component. The at least one parameter may include load capacity requirements (e.g., vertical/transverse load requirements, shear requirements, seismic requirements, etc.), building code requirements (specific to location, including soils, seismic, wind, etc.), building use or type (e.g., low/high rise, Type 1-Type 5, etc.), structural layout, a location of the structural member within a building structure, thermal resistance objectives (R) or thermal performance requirements, environmental targets or requirements (embodied carbon/energy or carbon sink), cost constraints, etc.

The user interface engine 210 may receive the framing design input information based on input received from a user, such as from at least one of a structural engineer, designer, builder, contractor, etc. The user interface engine 210 may be used to access a cloud-based BIM platform or similar for generating the framing design input information including at least one parameter for a structural component. In that regard, any cloud-based BIM platform or similar used for generating the framing design input information may be considered as the design computing device 104.

At block 404, the method may include processing, by at least one of the design computing device 104 and the optimization computing device 102, the framing design input information to identify the at least one parameter. For instance, the design input/output engine 212 of the design computing device 104 may process the framing design input information by extracting and/or packaging relevant data, such as the data specific to load, thermal, embodied carbon, cost requirements, cavity access location/MEPI requirements, or other requirements needed for carrying out an optimization process. In this instance, the design input/output engine 212 may send the processed framing design input information to the optimization computing device 102, and the design input/output engine 308 of the optimization computing device 102 may be configured to receive the processed framing design input information. In other examples, the design input/output engine 212 may send unprocessed framing design input information to the optimization computing device 102, and the design input/output engine 308 of the optimization computing device 102 can process the framing design requirement data by extracting relevant data and/or packaging the data into a suitable form for processing by the type of material recommendation engine 310.

At block 406, the method may include designating at least one type of material for the structural component based on a correlation between at least one property of the type of material and the at least one parameter of the structural component. For instance, in some examples, the type of material recommendation engine 310 may receive the processed framing design requirement data from the design input/output engine 308 (and/or the user interface engine 210), and then the type of material recommendation engine 310 may cross-reference the processed framing design requirement data for the structural component with property data for type of materials stored in the type of material data store 318. For instance, the method may include using the model conditions discussed above.

Based on a data correlation between the processed framing design requirement data and the property data for type of materials, the type of material recommendation engine 310 may designate at least one type of material for the structural component. As a specific example, a beam may be designated as having a specific load requirement, and the type of material recommendation engine 310 may, based on reference to mechanical or material properties of a categorized list of type of materials stored in the type of material data store 318, select at least one type of material for the beam. As another example, a wall panel may be designated as having a specific load requirement (and also optionally a specific thermal performance requirement, embodied carbon requirement, and/or cost requirement), and the type of material recommendation engine 310 may, based on reference to mechanical or material properties of a categorized list of type of materials, select at least one type of material for the wall panel (such as one of the hybrid bamboo panel structures disclosed herein). As yet another example, a header assembly panel for supporting a required wall cavity access location may be designated as having a specific load requirement (and also optionally a specific thermal performance requirement, embodied carbon requirement, and/or cost requirement), and the type of material recommendation engine 310 may, based on reference to mechanical or material properties of a categorized list of type of materials, select at least one type of material for the header assembly panel (such as one of the hybrid bamboo panel structures disclosed herein).

In some examples, the method may further include designating at least one type of material for a first structural component based on a correlation between at least one property of the type of material and at least one parameter of the first structural component and designating at least one type of material for a second structural component based on a correlation between at least one property of the type of material and at least one parameter of the second structural component. In some examples, the at least one parameter of the first structural component is a first load capacity and the at least one parameter of the second structural component is a second load capacity is lower than the first load capacity. In some examples, the at least one type of material designated for the first structural component has a stiffness or other mechanical property greater than the at least one type of material designated for the second structural component. In some examples, the at least one type of material designated for the first structural component has an embodied carbon lower than the at least one type of material designated for the second structural component.

In some examples, the method may further include custom fabricating the at least one type of material to define a structural component of the at least one type of material. The dimensions of the structural component for carrying out the custom fabrication may be defined by the location of the structural component within the frame relative to other structural components and/or the at least one parameter of the structural component. For instance, if the structural component is a wall panel, the dimensions will be defined by the location of the wall panel within the framing structure relative to the other wall panels and framing components. To carry out the method at block 408, the marking/fabrication computing system 106 may execute machine readable instructions to custom fabricate (such as by CNC cutting) the type of material(s) to create the structural component, e.g., a biogenic panel, framing component, etc.

In some examples, the method may further include adding at least one indicia to the structural component to indicate at least one of a type of material name, an optimization rating, and installation instructions. For instance, the marking/fabrication computing system 106 may be configured to execute machine readable instructions for custom printing on the structural component. In some examples, each structural component may include printed construction indicia that identifies the structural component, such as by its required location (e.g., by showing a visual representation of its location relative to the other framing members) such that the structural component of the at least one type of material is used in the designated location. The printed construction indicia may also include any instructions for installation (e.g., a MEPI map, nail pattern, etc.), an optimization rating generated by the optimization computing device 102 (indicating for instance, the load capacity, thermal performance rating, and/or embodied carbon of the panel or framing component, a designation or parameter indicating a grade of the panel or framing member, etc.), or other indicators or instructions.

In some examples, the method may further include providing a visual browser interface showing the position of each structural component of the at least one type of material relative to other components. In one example, the builder interface computing device 108 is configured to provide a visual browser interface such that contractors, subcontractors, a job site crew, etc., can view any plans, models, 3D construction orders or plans, etc., showing the position of each structural component of the at least one type of material (e.g., the location for each panel or component).

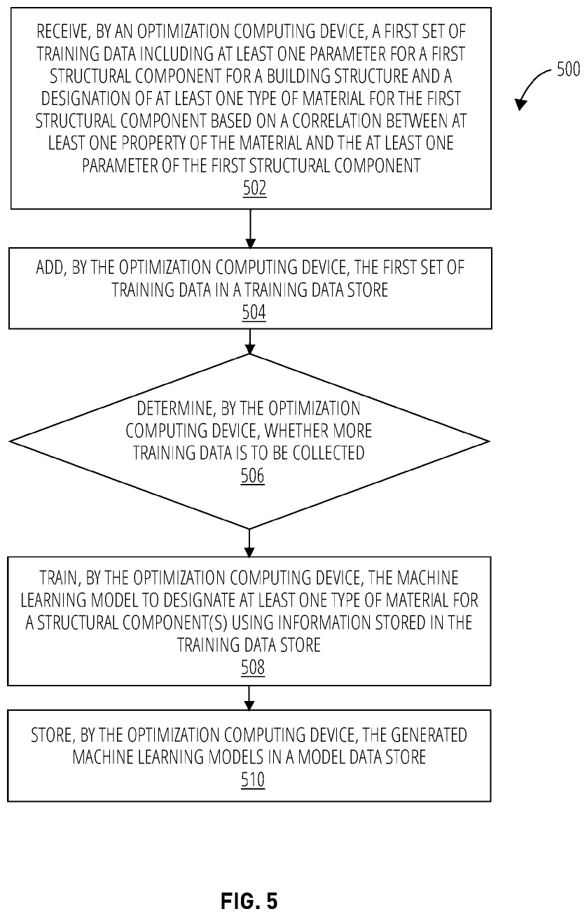

FIG. 5 is a flowchart that illustrates a non-limiting example of a method of training a machine learning model to optimize an industrialized construction system, including using at least one of the load, thermal, environmental capacities (e.g., embodied carbon/energy and/or carbon sink), costs, etc., of at least one structural component to train the model according to various aspects of the present disclosure. In the method 500, a set of training data is collected, and the optimization computing device 102 uses the training data to generate one or more machine learning models that can then be used to optimize a structural component or assembly having at least one structural component. According to some examples, the method includes training a machine learning model to designate a type of material for a structural component(s) to optimize at least one of the capacities of the structural component(s).

At block 502, a model training engine 312 of an optimization computing device 102 receives framing design input information including at least one parameter for a first structural component for a building structure as well as a designation of at least one type of material for the first structural component based on a correlation between at least one property of the type of material and the at least one parameter of the first structural component (“first set of training data”). For instance, the first set of training data may include framing design input information designating a required load and thermal performance for a structural component correlated with a load capacity and thermal rating of a type of material. The first set of training data may also include framing design input information having other parameters for the structural component, such as its location within the frame, the building type, local code requirements, embodied carbon requirements, cost constraints, etc.

In some examples, the first set of training data may be sent from or retrieved from at least one of the input/output engine 212, the input/output engine 308, and the type of material recommendation engine 310, as described above with respect to the method 400. In some examples, the training data may be retrieved from at least one BIM database or other data store.

At block 504, the model training engine 312 of the optimization computing device 102 stores the first set of training data in a training data store 316.

At decision block 506, a determination is made regarding whether more training data is to be collected. This determination may be based on a predetermined threshold amount of training data that is considered by an administrator to be enough for training the machine learning model. If it is determined that more training data is to be collected, then the result of decision block 506 is YES, and the method 500 returns to block 502 to collect training data for a second (or nth) structural component. Otherwise, if enough training data has been collected, then the result of decision block 506 is NO.

For instance, a threshold amount of training data may be needed to train a model to designate at least one type of material for a structural component based on a parameter that indicates the location of the structural component relative to other structural components in the building structure. More specifically, various training data sets containing designation of at least one type of material for a structural component having a load requirement (or other requirement) that also includes data pertaining to the location of structural component relative to other structural components in the building structure will be needed to train a model to designate at least one type of material for a structural component based only on its location relative to other structural components.

At block 508, the model training engine 312 trains one or more machine learning models using the training data stored in the training data store 316. In some examples, one or more machine learning models may be trained to process training data to designate one or more types of type of material(s) for at least one structural component. Generally, the one or more machine learning models are trained to produce an output of an optimization of at least one of a load capacity, thermal performance, embodied carbon, cost, cavity access location/MEPI requirements, or other criteria (e.g., acoustic performance, mold growth index, water vapor permeance, flame spread (fire safety), ballistic resistance, etc.) for at least a portion of building structure based on framing design input information including at least one parameter for a structural component or building received as input (such as load capacity, thermal performance requirement, embodied carbon, costs, cavity access location/MEPI requirements, etc.). For instance, the one or more machine learning models may be trained to use the model conditions discussed above.

In some examples, a first machine learning model may be trained to take a load capacity requirement of a structural component (optionally compared to load capacity requirements of one or more other structural components of the building structure) as input (and also optionally with thermal performance requirements, embodied carbon requirements, costs, and/or other requirements as input), and to output at least one type of material for the structural component.

In some examples, a second machine learning model may be trained to take an overall load capacity requirement of at least a portion of a building structure (e.g., a second story beam section) and an overall layout of the building structure as input (and also optionally with thermal performance requirements, embodied carbon requirements, and/or costs as input), and to output at least one type of material for at least one of the structural components.

In some examples, a third machine learning model may be trained to take an overall load capacity requirement of at least a portion of a building structure (such as based on building codes, building type/use, etc.) and an overall layout of the building structure as input (and also optionally with thermal performance requirements, embodied carbon requirements, costs, and/or other requirements as input), and to output at least one combination of types of material for structural components of the building structure (e.g., type of material A may be used for panel X beneath a beam whereas type of material B may be used for panel Y in a non-load bearing section of a wall).

In one example, the third machine learning model may further be trained to output the at least one combination of types of material for structural components of the building structure to the output engine 212 of the design computing device 104, and based upon further input from the user interface engine 210 of the design computing device 104, output information relating to the at least one combination of types of material for structural components of the building structure. For instance, in one example, the third machine learning model may further be trained to output a load, thermal performance, embodied carbon, and/or cost optimization rating of each of the combinations of types of material for structural components of the building structure.

In some examples, a fourth machine learning model may be trained to take design input information as input and to designate design criteria for the one or more types of material(s) as output such that a panel or structural member may be designed to meet the criteria. For instance, if a wall panel is designated as needing certain load capacities and dimensions, the fourth machine learning model may be trained to designate a wall panel design (such as by sending instructions to the fabrication computing system 106) to meet the load capacity requirements.

In some examples, a fifth machine learning model may be trained to take thermal resistance objectives and load capacity requirements (and/or embodied carbon requirements, cost restraints, or other requirements) as input and to output at least one type of material for the structural component. For instance, if a wall panel is designated as needing a first thermal level and load requirement (e.g., walls panels to support certain glazing/windows), the fifth machine learning model may be trained to designate a wall panel that has the required thermal and load capacities. In other instances, if at least a portion of a building structure is designated as needing thermal resistance objectives (R) at the minimum required by the code, the fifth machine learning model may be trained to designate a first structural component of the building structure having a first thermal performance rating and a first embodied carbon and/or first costs and a second structural component having a thermal performance rating higher or lower than the first thermal performance rating and a second embodied carbon and/or second costs higher or lower than the first embodied carbon and/or first costs.

In some examples, a sixth machine learning model may be trained to take embodied carbon requirements and load capacity requirements (and/or thermal performance requirements, cost restraints, and other requirements) as input and to output at least one type of material for the structural component or portion of the building. For instance, if building structure is designated as requiring an embodied carbon below a maximum level and having an overall load path requirement, the sixth machine learning model may be trained to designate one or more structural components that have the required embodied carbon and load capacities. As a specific example, a first type of material having a first embodied carbon property may be designated for a first structural member or portion of the frame having a first required load, and a second type of material having a second load capacity lower than the first load capacity may be designated for a second structural member of portion of the frame having a second required load lower than the first required load. For instance, if the first type of material had a higher embodied carbon than the second type of material, it would be environmentally beneficial to use the first type of material only where needed to support necessary loads or other requirements (e.g., thermal, acoustic, fire resistance, ballistic, etc.).

In some examples, a seventh machine learning model may be trained to take upfront and/or operating costs and load capacity requirements (and/or thermal performance requirements, embodied carbon requirements, and other requirements) as input and to output at least one type of material for the structural component or building. For instance, a first prefabricated building panel or structural member having a first upfront and/or operating costs and a first load capacity may be designated for a first portion of the frame having a first required load, and a second prefabricated building panel or structural member having a second upfront and/or operating costs lower than the first upfront and/or operating costs and a second load capacity lower than the first load capacity may be designated for the second portion of the frame having a second required load lower than the first required load.

In some examples, an eighth machine learning model may be trained to take an overall load capacity requirement of at least a portion of a building structure (e.g., a load-bearing wall(s) of a building) and an overall layout of the building structure as input (and also optionally with thermal performance requirements, embodied carbon requirements, and/or costs as input), and to designate a cavity access location for the portion of the building structure (e.g., a location of the wall cavity access in a load-bearing wall) when there is flexibility in the location of the cavity access.

For instance, the eighth machine learning model may be trained to designate possible wall cavity access location(s) based on structural load requirements for the building. As can be appreciated, a header assembly above a wall cavity access panel(s) may not provide the same vertical load support as a full height, on-edge prefabricated structural panel. In that regard, the eighth machine learning model may be trained to designate possible wall cavity access location(s) in areas of the building having lower load requirements (e.g., below a threshold level of vertical load), if the wall cavity access has flexibility in its location. In some instances, a wall cavity access location may be fixed because of MEPI requirements or other framing requirements. In such an instance, the eighth machine learning model may be trained to designate additional vertical load support (e.g., jack or king studs) or horizontal load support (e.g., additional header prefabricated structural panels or a different header assembly configuration) for that cavity access location.

In some examples, a ninth machine learning model (optionally combined with the eighth machine learning model) may be trained to take an overall load capacity requirement of at least a portion of a building structure (e.g., a load-bearing wall(s) of a building) and an overall layout of the building structure as input (and also optionally with thermal performance requirements, embodied carbon requirements, and/or costs as input) and to designate a header assembly configuration(s) for a required or preferred wall cavity access location of the portion of the building structure as output. For example, the ninth machine learning model may designate at least one of the header assemblies shown and described in U.S. Provisional Patent Application No. 63/520,459, incorporated herein, as output.

In one example, the eighth and/or ninth machine learning model may further be trained to output the cavity access location(s) and/or the header assembly configuration(s) for the portion of the building structure to the output engine 212 of the design computing device 104, and based upon further input from the user interface engine 210 of the design computing device 104, output information relating to the cavity access location and/or the header assembly configuration for the portion of the building structure. For instance, in one example, the eighth and/or ninth machine learning model may further be trained to output a load, thermal performance, embodied carbon, and/or cost optimization rating of each of the combinations of header assemblies (configuration, material, etc.) and wall cavity access locations, which may be received and processed for selection.

In some examples, a single machine learning model may be trained to carry out some or all of the functional aspects of the first, second, third, and fourth machine learning models. Moreover, it should be appreciated that other machine learning models may be trained to produce an output of an optimization of at least one of a load capacity, thermal performance, embodied carbon, cost, or other performance criteria (e.g., acoustic performance, mold growth index, water vapor permeance, flame spread (or fire safety generally), ballistic resistance, etc.) for at least a portion of building structure based on framing design input information including at least one parameter for a structural component or building received as input.

At block 510, the model training engine 312 stores the generated machine learning models in the model data store 314.

In some examples, the machine learning models may be neural networks, including but not limited to feedforward neural networks, convolutional neural networks, and recurrent neural networks. In some examples, any suitable training technique may be used, including but not limited to gradient descent (including but not limited to stochastic, batch, and mini-batch gradient descent).

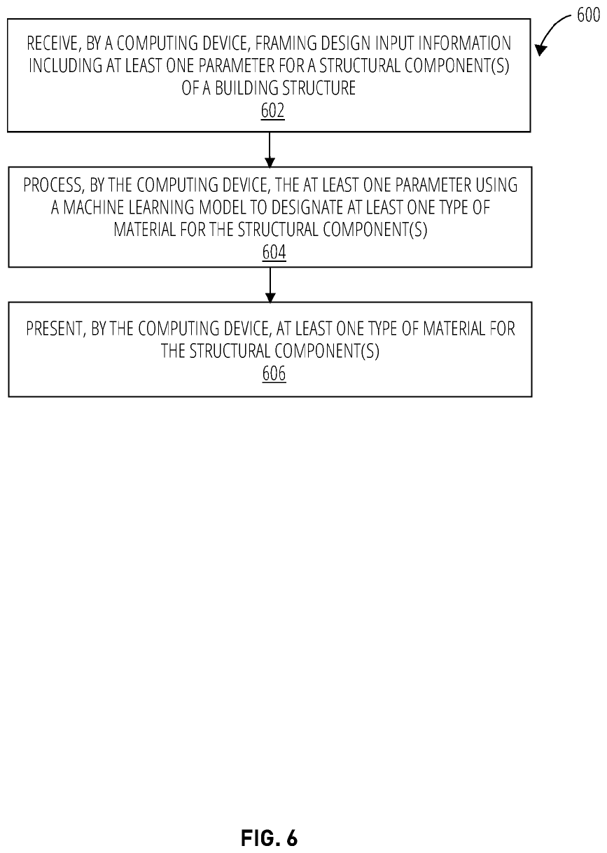

FIG. 6 is a flowchart that illustrates a non-limiting example of a method of using a machine learning model to optimize an industrialized construction system, including optimizing at least one of the load, thermal, environmental capacities (e.g., embodied carbon/energy and/or carbon sink), costs, cavity access locations, header configurations, etc., of a structural component(s) of an assembly (e.g., a building structure) and/or the assembly according to various aspects of the present disclosure. To optimize at least one of the load thermal, environmental, costs capacities, cavity access locations, and header configurations, of a structural component(s) or assembly, the method 600 may include using at least one machine learning model to designate one or more types of type of material(s) for at least one structural component.

In the method 600, the type of material recommendation engine 310 uses the one or more machine learning models generated by the method 500 discussed above in order to designate one or more types of type of material(s) for at least one structural component of a “current” building design or structure (for simulation or actual use), whereas the training data sets used to train the machine learning models are based on data pertaining to structural components used in “past” building designs or structures (i.e., partially or fully completed building structures from designs that were at least one of configured for testing/review, approved for use in a construction plan, used for analyzing simulated or actual building structures, etc.).

At block 602, the method may include receiving, by a computing device (such as the design computing device 104), framing design input information including at least one parameter for a structural component(s) (such as a beam, post, joist, header, truss, wall panel, a wall having a wall cavity access location, a header panel, etc.) or at least a characteristic of a building (e.g., layout, codes, use, type, etc.). For instance, the user interface engine 210 of the design computing device 104 may receive the framing design input information including at least one parameter for a structural component(s). The at least one parameter may include load capacity requirements (e.g., vertical/transverse load requirements, shear requirements, seismic requirements, etc.), building code requirements (specific to location, including soils, seismic, wind, etc.), building use or type (e.g., low/high rise, Type 1-Type 5, etc.), structural layout, a location of the structural member within a building structure, thermal resistance objectives (R) or thermal performance requirements, environmental targets or requirements (embodied carbon/energy or carbon sink), cost constraints, etc.

The user interface engine 210 may receive the framing design input information based on input received from a user, such as from at least one of a structural engineer, designer, builder, contractor, etc. The user interface engine 210 may be used to access a cloud-based BIM platform or similar for generating the framing design input information including at least one parameter for a structural component. In that regard, any cloud-based BIM platform or similar used for generating the framing design input information may be considered as the design computing device 104.

The method may include processing, by a computing device (such as the optimization computing device 102), the framing design input information to identify the at least one parameter. In one example, the method may include using one or more machine learning models to identify the at least one parameter. For instance, the machine learning models may identify the at least one parameter based on training data retrieved for similar structural components where the at least one parameter was used to designate at least one type of material for the structural component(s).

Before processing the framing design input information, the method may include extracting and/or packaging relevant data from the framing design input information using the output engine 212 or output engine 308 using block 504 of the method 500. In other examples, the design input/output engine 212 may send unprocessed framing design input information to the optimization computing device 102, and the type of material recommendation engine 310 of the optimization computing device 102 can process the framing design requirement data by extracting relevant data and/or packaging the data into a suitable form for processing using one or more of the machine learning models.

At block 604, the method may include using a machine learning model to designate one or more types of type of material(s) for at least one structural component of a building structure as output based on the at least one parameter of the structural component(s).

In some examples, the method may include using a machine learning model to designate at least one type of material for the structural component(s) based on a correlation between at least one property of the type of material and the at least one parameter of the structural component(s). In some examples, the method may include using a machine learning model used to carry out one or more aspects of the model conditions discussed above. For instance, in some examples, the type of material recommendation engine 310 may input a load capacity requirement of a structural component (based on the processed framing design requirement data) to the machine learning model. Upon receiving the input, the machine learning model may output at least one type of material for the structural component(s).

In some examples, the method may include providing at least one structural component dimension to the machine learning model as input such that the machine learning model may designate at least one of a load capacity and an embodied carbon capacity for at least one type of material having the structural component dimensions as output. For instance, the type of material recommendation engine 310 may input structural component dimensions to the machine learning model, and the machine learning model may output capacities (e.g., load capacities, thermal capacities, embodied carbon capacities, costs, etc.) for at least one type of material having the structural component dimensions.

In some examples, the method may include using a machine learning model to designate at least one type of material for a first structural component as output based on a correlation between at least one property of the type of material and at least one parameter of the first structural component and designating at least one type of material for a second structural component as output based on a correlation between at least one property of the type of material and at least one parameter of the second structural component. In some examples, the at least one parameter of the first structural component is a first load capacity and the at least one parameter of the second structural component is a second load capacity is lower than the first load capacity. In some examples, the at least one type of material designated by the machine learning model for the first structural component has a stiffness or other mechanical property greater than the at least one type of material designated for the second structural component. In some examples, the at least one type of material designated by the machine learning model for the first structural component has an embodied carbon lower than the at least one type of material designated for the second structural component.

In some examples, the method may include using a machine learning model to designate at least one type of material for at least one of the structural components of a building structure based on an overall load capacity requirement of at least a portion of a building structure as input (and also optionally with thermal performance requirements, embodied carbon requirements, and other requirements as input). For instance, a user (such as a structural engineer) may provide, as input to the machine learning model, loads that need to be applied to at least one of the structural components based on the use of the component (e.g., the location of the beam, the location of the wall panel, etc., and the load it needs to support). The user may further provide, as input to the machine learning model, at least one of several locations for the structural component, a span length of a beam/joist, termination points of a beam/joist, connection between any of the components, etc. Based on the inputs, the machine learning model may designate at least one type of material for at least one of the structural components of a building structure.

In some examples, the method may include using a machine learning model to designate at least one type of material for first and second structural components as output based on the location of the structural components the building structure as input (and also optionally with thermal performance requirements, embodied carbon requirements, and other requirements as input), where the first structural component is located in a first location of the building structure, and the second structural component is located in a second location of the building structure. In one example, the machine learning model may designate at least first and second types of type of material for a first structural component located in a first location of the building structure, and at least first and second types of type of material for a second structural component located in a second location of the building structure. In one example, the machine learning model may further provide an optimization rating for each combination of types of material for the first and second structural components located in first and second locations of a building structure.

Such a machine learning model may benefit a designer when trying to choose types of type of material (e.g., materials, dimensions, ratings, etc.) for various structural components of a building. For instance, a structural engineer may choose a type(s) of type of material for structural component(s) for an upper portion of a building structure, and then based on the materials chosen for the upper portion, the structural engineer may need to use types of type of material at lower portions of a building that use more material (e.g., thicker panels) or that use more expensive material (higher grade) to support the overall structure. Accordingly, the machine learning model may be used by the structural engineer to try multiple combinations of types of material for the various components to determine which combination of types of material optimizes the load and/or embodied carbon capacities of the structure. In that regard, the method may include performing multiple iterations of the step of using a machine learning model to designate at least one type of material for first and second structural components as output based on the location of the structural components the building structure as input (and also optionally with thermal performance requirements, embodied carbon requirements, and other requirements as input), where the first structural component is located in a first location of the building structure, and the second structural component is located in a second location of the building structure.

In some examples, the method may include using a machine learning model to take design input information as input and to designate design criteria for the one or more types of type of material(s) as output such that a panel or structural member may be designed to meet the criteria. For instance, if a wall panel is designated as needing certain load capacities and dimensions, the machine learning model may designate a wall panel design (such as by sending instructions to the fabrication computing system 106) to meet the load capacity requirements.

In some examples, the method may include using a machine learning model to take thermal performance objectives and load capacity requirements (and/or embodied carbon requirements, cost restraints, or other requirements) as inputs and to output at least one type of material for the structural component. For instance, if a wall panel is designated as needing a first thermal level and load requirement (e.g., walls panels to support certain glazing/windows), the machine learning model may designate a wall panel that has the required thermal and load capacities. In other instances, if at least a portion of a building structure is designated as needing thermal performance objectives at the minimum required by the code, the machine learning model may designate a first structural component of the building structure having a first thermal performance rating and a first embodied carbon and/or first costs and a second structural component having a thermal performance rating higher or lower than the first thermal performance rating and a second embodied carbon and/or second costs higher or lower than the first embodied carbon and/or first costs.

In some examples, the method may include using a machine learning model to take embodied carbon requirements and load capacity requirements (and/or thermal performance requirements, cost restraints, and other requirements) as input and to output at least one type of material for the structural component or portion of the building. For instance, if building structure is designated as requiring an embodied carbon below a maximum level and having an overall load path requirement, the sixth machine learning model may be trained to designate one or more structural components that have the required embodied carbon and load capacities. As a specific example, a first type of material having a first embodied carbon property may be designated for a first structural member or portion of the frame having a first required load, and a second type of material having a second load capacity lower than the first load capacity may be designated for a second structural member of portion of the frame having a second required load lower than the first required load. For instance, if the first type of material had a higher embodied carbon than the second type of material, it would be environmentally beneficial to use the first type of material only where needed to support necessary loads or other requirements (e.g., thermal, acoustic, fire resistance, ballistic, etc.).

In some examples, the method may include using a machine learning model to take upfront and/or operating costs and load capacity requirements (and/or thermal performance requirements, embodied carbon requirements, and other requirements) as input and to output at least one type of material for the structural component or building. For instance, a first prefabricated building panel or structural member having a first upfront and/or operating costs and a first load capacity may be designated for a first portion of the frame having a first required load, and a second prefabricated building panel or structural member having a second upfront and/or operating costs lower than the first upfront and/or operating costs and a second load capacity lower than the first load capacity may be designated for the second portion of the frame having a second required load lower than the first required load.

In some examples, the method may include using a machine learning model to take an overall load capacity requirement of at least a portion of a building structure (e.g., a load-bearing wall(s) of a building) and an overall layout of the building structure as input (and also optionally with thermal performance requirements, embodied carbon requirements, and/or costs as input), as input, and to output a cavity access location(s) for the portion of the building structure (e.g., a location of the wall cavity access in a load-bearing wall). For instance, the method may include using a machine learning model to designate wall cavity access locations based on structural load requirements for the building, such as in areas of the building having lower load requirements (e.g., below a threshold level of vertical load) if the wall cavity access has flexibility in its location.

In some examples, the method may include using a machine learning model to take an overall load capacity requirement of at least a portion of a building structure (e.g., a load-bearing wall(s) of a building) and an overall layout of the building structure as input (and also optionally with thermal performance requirements, embodied carbon requirements, and/or costs as input) as input, and to output a header assembly configuration(s) for a required wall cavity access location of the portion of the building structure as output. For example, the machine learning model may designate one of the header assemblies shown and described in U.S. Provisional Patent Application No. 63/520,459, incorporated herein, as output.

At block 606, the method may include presenting, by the optimization computing device 102, at least one type of material for the structural component on at least one of the optimization computing device 102, the design computing device 104, and the builder interface computing device 108.

In some examples, the method may further include custom fabricating the at least one type of material to define a structural component of the at least one type of material, as discussed above for method 500.

In some examples, the method may further include adding at least one indicia to the structural component to indicate at least one of a type of material name, an optimization rating, and installation instructions, as discussed above for method 500.

In some examples, the method may further include providing a visual browser interface showing the position of each structural component of the at least one type of material, as discussed above for method 500.

Although the example methods 400, 500, and 600 depicts a particular sequence of operations, the sequence may be altered without departing from the scope of the present disclosure. For example, some of the operations depicted may be performed in parallel or in a different sequence that does not materially affect the function of methods 400, 500, and 600. In yet some examples, some of the steps of methods 400, 500, and 600 may be omitted. In other examples, different components of an example device or system may be used to implement the methods 400, 500, and 600.

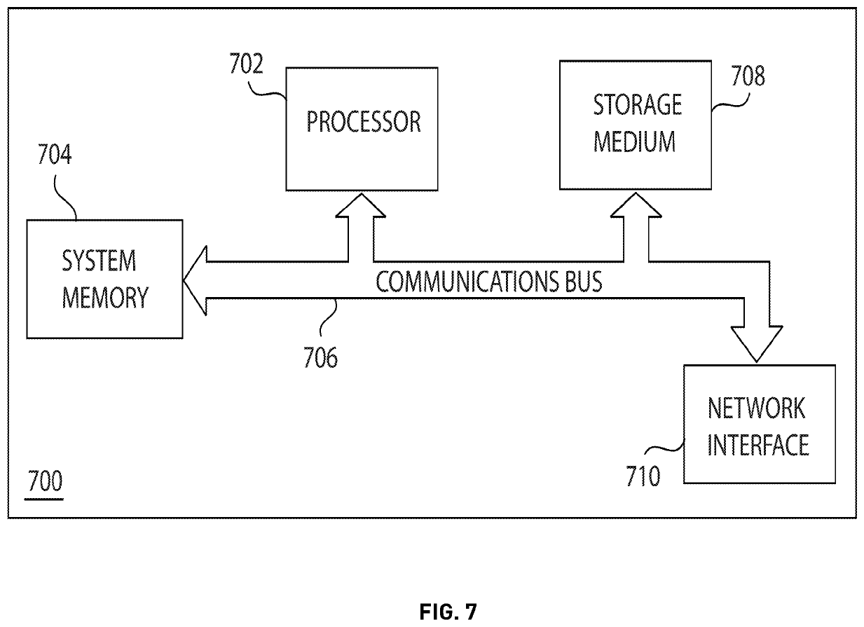

FIG. 7 is a block diagram that illustrates aspects of an exemplary computing device 700 appropriate for use as a computing device of the present disclosure. While multiple different types of computing devices were discussed above, the exemplary computing device 700 describes various elements that are common to many different types of computing devices. While FIG. 7 is described with reference to a computing device that is implemented as a device on a network, the description below is applicable to servers, personal computers, mobile phones, smart phones, tablet computers, embedded computing devices, and other devices that may be used to implement portions of examples of the present disclosure. Moreover, those of ordinary skill in the art and others will recognize that the computing device 700 may be any one of any number of currently available or yet to be developed devices.

In its most basic configuration, the computing device 700 includes at least one processor 702 and a system memory 704 connected by a communication bus 706. Depending on the exact configuration and type of device, the system memory 704 may be volatile or nonvolatile memory, such as read only memory (“ROM”), random access memory (“RAM”), EEPROM, flash memory, or similar memory technology. Those of ordinary skill in the art and others will recognize that system memory 704 typically stores data and/or program modules that are immediately accessible to and/or currently being operated on by the processor 702. In this regard, the processor 702 may serve as a computational center of the computing device 700 by supporting the execution of instructions.

As further illustrated in FIG. 7, the computing device 700 may include a network interface 710 comprising one or more components for communicating with other devices over a network. Examples of the present disclosure may access basic services that utilize the network interface 710 to perform communications using common network protocols. The network interface 710 may also include a wireless network interface configured to communicate via one or more wireless communication protocols, such as Wi-Fi, 2G, 3G, LTE, WiMAX, Bluetooth, Bluetooth low energy, and/or the like. As will be appreciated by one of ordinary skill in the art, the network interface 710 illustrated in FIG. 7 may represent one or more wireless interfaces or physical communication interfaces described and illustrated above with respect to particular components of the system 100.

In the example depicted in FIG. 7, the computing device 700 also includes a storage medium 708. However, services may be accessed using a computing device that does not include means for persisting data to a local storage medium. Therefore, the storage medium 708 depicted in FIG. 7 is represented with a dashed line to indicate that the storage medium 708 is optional. In any event, the storage medium 708 may be volatile or nonvolatile, removable or nonremovable, implemented using any technology capable of storing information such as, but not limited to, a hard drive, solid state drive, CD ROM, DVD, or other disk storage, magnetic cassettes, magnetic tape, magnetic disk storage, and/or the like.

As used herein, the term “computer-readable medium” includes volatile and non-volatile and removable and non-removable media implemented in any method or technology capable of storing information, such as computer readable instructions, data structures, program modules, or other data. In this regard, the system memory 704 and storage medium 708 depicted in FIG. 7 are merely examples of computer-readable media.

Suitable implementations of computing devices that include a processor 702, system memory 704, communication bus 706, storage medium 708, and network interface 710 are known and commercially available. For ease of illustration and because it is not important for an understanding of the claimed subject matter, FIG. 7 does not show some of the typical components of many computing devices. In this regard, the computing device 700 may include input devices, such as a keyboard, keypad, mouse, microphone, touch input device, touch screen, tablet, and/or the like. Such input devices may be coupled to the computing device 700 by wired or wireless connections including RF, infrared, serial, parallel, Bluetooth, Bluetooth low energy, USB, or other suitable connections protocols using wireless or physical connections. Similarly, the computing device 700 may also include output devices such as a display, speakers, printer, etc. Since these devices are well known in the art, they are not illustrated or described further herein.

Various examples of the disclosure are discussed in detail above. While specific implementations are discussed, it should be understood that this is done for illustration purposes only. A person skilled in the relevant art will recognize that other components and configurations may be used without departing from the spirit and scope of the disclosure. Thus, the description and drawings provided herein are illustrative and are not to be construed as limiting.

Numerous specific details are described to provide a thorough understanding of the disclosure. However, in certain instances, well-known or conventional details are not described in order to avoid obscuring the description. Additional features and advantages of the disclosure will be set forth in the description which follows, and in part will be obvious from the description, or can be learned by practice of the herein disclosed principles. The features and advantages of the disclosure can be realized and obtained by means of the assemblies, methods, and combinations particularly pointed out in the appended claims. These and other features of the disclosure will become more fully apparent from the following description and appended claims or can be learned by the practice of the principles set forth herein.

While the concepts of the present disclosure are susceptible to various modifications and alternative forms, specific examples thereof have been shown by way of example in the drawings and have been described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one example,” “an example,” “an illustrative example,” etc., indicate that the example described may include a particular feature, structure, or characteristic, but every example may or may not necessarily include that particular feature, structure, or characteristic. Moreover, such phrases are not necessarily referring to the same example. Further, when a particular feature, structure, or characteristic is described in connection with an example, it is submitted that it is within the knowledge of one skilled in the art to affect such feature, structure, or characteristic in connection with other examples whether or not explicitly described.

As used herein, the terms “about” and “approximately,” in reference to a number, is used herein to include numbers that fall within a range of 10%, 5%, or 1% in either direction (greater than or less than) the number unless otherwise stated or otherwise evident from the context (except where such number would exceed 100% of a possible value).

Language such as “top”, “bottom”, “upper”, “lower”, “vertical”, “horizontal”, “lateral”, etc., in the present disclosure is meant to provide orientation for the reader with reference to the drawings and is not intended to be the required orientation of the components or to impart orientation limitations into the claims.

In the drawings, some structural or method features may be shown in specific arrangements and/or orderings. However, it should be appreciated that such specific arrangements and/or orderings may not be required. Rather, in some examples, such features may be arranged in a different manner and/or order than shown in the illustrative figures. Additionally, the inclusion of a structural or method feature in a particular figure is not meant to imply that such feature is required in all examples and, in some examples, it may not be included or may be combined with other features.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term.

Likewise, the disclosure is not limited to various examples given in this specification. Unless otherwise defined, technical and scientific terms used herein have the meaning as commonly understood by one of ordinary skill in the art to which this disclosure pertains. In the case of conflict, the present document, including definitions will control.

Note that titles or subtitles may be used in the examples for convenience of a reader, which in no way should limit the scope of the disclosure.

While illustrative examples have been illustrated and described, it will be appreciated that various changes can be made therein without departing from the spirit and scope of the disclosure.

### INVENTIVE CONCEPTS

Clause 1. A method for optimizing industrialized construction capacities of a building structure, comprising: receiving, by at least one of a design computing device and an optimization computing device, framing design input information including at least one parameter for at least one structural component; processing, by at least one of the design computing device and the optimization computing device, the framing design input information to identify the at least one parameter; and designating, by the optimization computing device, at least one type of material for the at least one structural component based on a correlation between at least one property of the type of material and the at least one parameter of the at least one structural component.

Clause 2. The method of clause 1, further comprising designating at least one type of material for a first structural component based on a correlation between at least one property of the type of material and at least one parameter of the first structural component and designating at least one type of material for a second structural component based on a correlation between at least one property of the type of material and at least one parameter of the second structural component.

Clause 3. The method of clause 2, wherein the at least one parameter of the first structural component is a first load capacity and the at least one parameter of the second structural component is a second load capacity is lower than the first load capacity.

Clause 4. The method of clause 3, wherein the at least one type of material designated for the first structural component has a stiffness or other mechanical property greater than the at least one type of material designated for the second structural component.

Clause 5. The method of clause 3 or claim 4, wherein the at least one type of material designated for the first structural component has an embodied carbon lower than the at least one type of material designated for the second structural component.

Clause 6. The method of clause 1, further comprising custom fabricating, by a fabrication computing system, the at least one type of material to define the at least one structural component of the at least one type of material.

Clause 7. The method of clause 6, further comprising adding at least one indicia to the at least one structural component of the at least one type of material to indicate at least one of a type of material name, an optimization rating, and installation instructions.

Clause 8. The method of clause 7, wherein the optimization rating indicates at least one of a load capacity, a thermal performance rating, an environmental capacity, and a cost of the at least one structural component of the at least one type of material.

Clause 9. The method of clause 7, wherein the installation instructions include a location of the at least one structural component of the at least one type of material relative to at least one other structural component of the building structure.

Clause 10. The method of clause 1, further comprising providing a visual browser interface showing a position of the at least one structural component of the at least one type of material relative to at least one other structural component of the building structure.

Clause 11. The method of clause 1, wherein the at least one parameter of the at least one structural component includes at least one of a load capacity, thermal performance requirements, embodied carbon/energy requirements, carbon sink requirements, and cost requirements.

Clause 12. The method of clause 1, wherein the at least one parameter of the at least one structural component includes at least one of load capacity requirements, building code requirements, building use, building type, structural layout, a location of the structural member within a building structure, thermal resistance objectives, thermal performance requirements, embodied carbon/energy requirements, carbon sink requirements, cost requirements, cavity access location requirements, and MEPI requirements.

Clause 13. A system for optimizing industrialized construction capacities of a building structure, the system comprising: a computing device having at least one processor and a non-transitory computer-readable medium; wherein the non-transitory computer-readable medium has a data store and computer-executable instructions stored thereon; and wherein the instructions, in response to execution by the at least one processor, cause the computing device to perform actions comprising: receiving, by the computing device, framing design input information including at least one parameter for at least one structural component; processing, by the computing device, the framing design input information to identify the at least one parameter; and designating, by the computing device, at least one type of material for the at least one structural component based on a correlation between at least one property of the type of material and the at least one parameter of the at least one structural component.

Clause 14. The system of clause 13, wherein the instructions, in response to execution by the at least one processor, cause the computing device to perform actions further comprising: designating at least one type of material for a first structural component based on a correlation between at least one property of the type of material and at least one parameter of the first structural component and designating at least one type of material for a second structural component based on a correlation between at least one property of the type of material and at least one parameter of the second structural component.

Clause 15. The system of clause 14, wherein the at least one parameter of the first structural component is a first load capacity and the at least one parameter of the second structural component is a second load capacity is lower than the first load capacity.

Clause 16. The system of clause 15, wherein the at least one type of material designated for the first structural component has a stiffness or other mechanical property greater than the at least one type of material designated for the second structural component.

Clause 17. The system of clause 15 or claim 16, wherein the at least one type of material designated for the first structural component has an embodied carbon lower than the at least one type of material designated for the second structural component.

Clause 18. The system of clause 13, further comprising a fabrication computing system configured to custom fabricate the at least one type of material to define the at least one structural component of the at least one type of material.

Clause 19. The system of clause 18, further comprising a marking computing system configured to add at least one indicia to the at least one structural component of the at least one type of material to indicate at least one of a type of material name, an optimization rating, and installation instructions.

Clause 20. The system of clause 19, wherein the optimization rating indicates at least one of a load capacity and an embodied carbon of the at least one structural component of the at least one type of material.

Clause 21. The system of clause 19, wherein the installation instructions include a location of the at least one structural component of the at least one type of material relative to at least one other structural component of the building structure.

Clause 22. The system of clause 13, further comprising a builder interface computing device configured to provide a visual browser interface showing a position of the at least one structural component of the at least one type of material relative to at least one other structural component of the building structure.

Clause 23. The system of clause 13, wherein the at least one parameter of the at least one structural component includes at least one of a load capacity, thermal performance requirements, embodied carbon/energy requirements, carbon sink requirements, and cost requirements.

Clause 24. The system of clause 13, wherein the at least one parameter of the at least one structural component includes at least one of load capacity requirements, building code requirements, building use, building type, structural layout, a location of the structural member within a building structure, thermal resistance objectives, thermal performance requirements, embodied carbon/energy requirements, carbon sink requirements, cost requirements, cavity access location requirements, and MEPI requirements.

Clause 25. A method of training a machine learning model to optimize industrialized construction capacities of a building structure, the method comprising: receiving, by an optimization computing device, a first set of training data including at least one parameter for a first structural component for a building structure and a designation of at least one type of material for the first structural component based on a correlation between at least one property of the type of material and the at least one parameter of the first structural component; adding, by the optimization computing device, the first set of training data in a training data store; and training, by the optimization computing device, the machine learning model to designate at least one type of material for at least one structural component using information stored in the training data store.

Clause 26. The method of clause 25, further comprising training, by the optimization computing device, a machine learning model that processes a load capacity requirement of at least one structural component as input to produce a designation of at least one type of material for the at least one structural component as output.

Clause 27. The method of clause 25, further comprising training, by the optimization computing device, a machine learning model that processes a load capacity requirement of a structural component compared to load capacity requirements of one or more other structural components of the building structure as input to produce a designation of at least one type of material for the at least one structural component as output.

Clause 28. The method of any of clause 25, further comprising training, by the optimization computing device, a machine learning model to take an overall load capacity requirement of at least a portion of a building structure and an overall layout of the building structure as input to produce at least one type of material for at least one structural component of the building structure as output.

Clause 29. The method of any of clause 25, further comprising training, by the optimization computing device, a machine learning model to take an overall load capacity requirement of at least a portion of a building structure and an overall layout of the building structure as input to produce at least one combination of types of material for structural components of the building structure as output.

Clause 30. The method of clause 29, further comprising training, by the optimization computing device, the machine learning model to output the at least one combination of types of material for structural components of the building structure to a design computing device, and based upon further input from the design computing device, producing information relating to the at least one combination of types of material for structural components of the building structure as output.

Clause 31. The method of clause 30, further comprising training, by the optimization computing device, the machine learning model to produce at least one of a load, thermal performance, cost, or environmental optimization rating of each of the combinations of types of material for structural components of the building structure as output.

Clause 32. The method of any of clauses 25-31, wherein the at least one parameter of the first structural component includes at least one of load capacity requirements, building code requirements, building use, building type, structural layout, a location of the structural component within a building structure, thermal resistance objectives, thermal performance requirements, embodied carbon/energy requirements, carbon sink requirements, cost requirements, cavity access location requirements, and MEPI requirements.

Clause 33. The method of clause 32, further comprising training, by the optimization computing device, the machine learning model to output the at least one type of material for the at least one structural component based on thermal resistance objectives or requirements and at least one of load capacity requirements, embodied carbon requirements, cost restraints, cavity access location requirements, and MEPI requirements as input.

Clause 34. The method of clause 25, further comprising training, by the optimization computing device, the machine learning model to output the at least one type of material for the at least one structural component based on embodied carbon requirements and at least one of load capacity requirements, thermal resistance objectives or requirements, cost restraints, cavity access location requirements, and MEPI requirements as input.

Clause 35. The method of clause 25, further comprising training, by the optimization computing device, the machine learning model to output the at least one type of material for the at least one structural component based on upfront and/or operating costs of and at least one of load capacity requirements, thermal performance requirements, and environmental requirements.

Clause 36. A method of using a machine learning model to optimize industrialized construction capacities of a building structure, the method comprising: receiving, by a computing device, framing design input information including at least one parameter for at least one structural component of a building structure; processing, by the computing device, the at least one parameter as input using a machine learning model to designate at least one type of material for the at least one structural component; and presenting, by the computing device, at least one type of material for the at least one structural component.

Clause 37. The method of clause 36, wherein processing, by the computing device, the at least one parameter as input using a machine learning model to designate at least one type of material for the at least one structural component as output is based on a correlation between at least one property of the type of material and the at least one parameter of the structural component.

Clause 38. The method of clause 36, further comprising processing, by the computing device, at least one structural component dimension as input using the machine learning model to designate at least one of a load capacity and an environmental capacity for at least one type of material having the structural component dimensions as output.

Clause 39. The method of clause 36, further comprising processing, by the computing device, a correlation between at least one property of a type of material and at least one parameter of a first structural component and a correlation between at least one property of the type of material and at least one parameter of a second structural component as input using the machine learning model to designate at least one type of material for the second structural component as output.

Clause 40. The method of clause 36, further comprising processing, by the computing device, an overall load capacity requirement of at least a portion of a building structure as input using a machine learning model to designate at least one type of material for at least one of the structural components of a building structure as output.

Clause 41. The method of clause 36, further comprising processing, by the computing device, a location of first and second structural components the building structure as input, where the first structural component is located in a first location of the building structure, and the second structural component is located in a second location of the building structure, and using a machine learning model to designate at least one type of material for the first and second structural components as output.

Clause 42. The method of clause 41, further comprising using the machine learning model to designate at least first and second types of type of material for the first structural component located in the first location of the building structure, and at least first and second types of type of material for the second structural component located in the second location of the building structure.

Clause 43. The method of clause 42, further comprising using the machine learning model to provide an optimization rating for each combination of types of material for the first and second structural components located in first and second locations of the building structure.

Clause 44. The method of clause 36, further comprising processing, by the computing device at least one of structural component dimension, location, and load requirement as input, and using the machine learning model to designate at least one of a load capacity and an environmental capacity for at least one type of material having the structural component dimensions, location, or load requirements as output.

Clause 45. The method of clause 36 or claim 45, further comprising custom fabricating, by a fabrication computing system, the at least one type of material to define a structural component of the at least one type of material.

Clause 46. The method of clause 45, further comprising adding at least one indicia to the structural component of the at least one type of material to indicate at least one of a type of material name, an optimization rating, and installation instructions.

Clause 47. The method of clause 46, wherein the optimization rating indicates at least one of a load capacity, thermal capacity, cost, and an environmental capacity of the at least one structural component of the at least one type of material.

Clause 48. The method of clause 46, wherein the installation instructions include a location of the at least one structural member of the at least one type of material relative to at least one other structural component of the building structure.

Clause 49. The method of clause 36, further comprising providing a visual browser interface showing a position of the at least one structural component of the at least one type of material relative to at least one other structural component of the building structure.

Clause 50. The method of clause 36, wherein the at least one parameter of the at least one structural component includes at least one of load capacity requirements, building code requirements, building use, building type, structural layout, a location of the structural component within a building structure, thermal resistance objectives, thermal performance requirements, embodied carbon/energy requirements, carbon sink requirements, cost requirements, cavity access location requirements, and MEPI requirements.

Clause 51. The method of clause 36, further comprising processing, by the computing device, at least one of structural component dimension, location, load requirement, thermal resistance objectives or requirements, embodied carbon requirements, and cost restraints as input and using the machine learning model to designate at least one type of material for the at least one structural component as output.

Clause 52. A method for optimizing industrialized construction capacities of a building structure, comprising: receiving, by at least one of a design computing device and an optimization computing device, framing design input information including at least one parameter for at least one structural component; processing, by at least one of the design computing device and the optimization computing device, the framing design input information to identify the at least one parameter; and designating, by the optimization computing device, at least one type of material for the at least one structural component based on a correlation between at least one property of the type of material and the at least one parameter of the at least one structural component; custom fabricating, by a fabrication computing system, the at least one type of material to define the at least one structural component of the at least one type of material; and adding at least one indicia to the at least one structural component of the at least one type of material to indicate at least one of a type of material name, an optimization rating, and installation instructions.

Clause 53. The method of clause 52, further comprising designating by the optimization computing device, at least one type of material for a first structural component based on a correlation between at least one property of the type of material and at least one parameter of the first structural component and designating at least one type of material for a second structural component based on a correlation between at least one property of the type of material and at least one parameter of the second structural component.

Clause 54. The method of clause 53, wherein the at least one parameter of the first structural component is a first load capacity and the at least one parameter of the second structural component is a second load capacity is lower than the first load capacity.

Clause 55. The method of clause 54, wherein the at least one type of material designated for the first structural component has a stiffness or other mechanical property greater than the at least one type of material designated for the second structural component.

Clause 56. The method of clause 54 or claim 57, wherein the at least one type of material designated for the first structural component has an embodied carbon lower than the at least one type of material designated for the second structural component.

Clause 57. The method of clause 52, wherein the optimization rating indicates at least one of a load capacity, a thermal performance rating, an environmental capacity, and a cost of the at least one structural component of the at least one type of material.

Clause 58. The method of clause 52, wherein the installation instructions include a location of the at least one structural member of the at least one type of material relative to at least one other structural component of the building structure.

Clause 59. The method of clause 52, further comprising providing a visual browser interface showing a position of the at least one structural component of the at least one type of material relative to at least one other structural component of the building structure.

Clause 60. The method of clause 52, wherein the at least one parameter of the at least one structural component includes at least one of load capacity requirements, building code requirements, building use, building type, structural layout, a location of the structural member within a building structure, thermal resistance objectives, thermal performance requirements, embodied carbon/energy requirements, carbon sink requirements, cost requirements, cavity access location requirements, and MEPI requirements.

Clause 61. The method of clause 52, further comprising providing a visual browser interface showing a position of the at least one structural component of the at least one type of material relative to at least one other structural component of the building structure.

Clause 62. A method for optimizing construction capacities of a building structure using prefabricated structural panels, comprising: receiving, with a computing device, framing design input information including wall cavity access requirements for at least one wall formed with at least one prefabricated structural panel; processing, with a computing device, the framing design input information to determine at least one load requirement for the at least one wall; and designating, by a computing device, at least one of a wall cavity access location for the at least one wall and a header assembly configuration based on structural load requirements for the at least one wall.

Clause 63. The method of Claim 62, further comprising designating a type of material for the header assembly.

Clause 64. The method of Claim 63, wherein at least one property of the type of material is a load capacity of the type of material.

Clause 65. The method of Claim 62, further comprising custom fabricating, by a fabrication computing system, the at least one prefabricated structural panel, the header assembly, and a wall cavity access panel(s) for enclosing a wall cavity access location.

Clause 66. The method of clause 65, further comprising adding at least one indicia to each of the at least one prefabricated structural panel, the header assembly, and the wall cavity access panel(s) to indicate at least one of a type of material, an optimization rating, and installation instructions.

Clause 67. The method of clause 66, wherein the optimization rating indicates at least one of a load capacity, a thermal performance rating, an environmental capacity, and a cost of the at least one prefabricated structural panel, the header assembly, and the wall cavity access panel(s).

Clause 68. The method of clause 66, wherein the installation instructions of the wall cavity access panel(s) include a location of the wall cavity access panel(s) relative to a location of the at least one prefabricated structural panel and the header assembly.

Clause 69. The method of clause 66, further comprising providing a visual browser interface showing a position of the wall cavity access panel(s) relative to a location of the at least one prefabricated structural panel and the header assembly.

Clause 70. The method of clause 67, further comprising designating, by a computing device, a wall cavity access location in a first area of the at least one wall having a vertical load requirement below a threshold level of vertical load.

Clause 71. The method of clause 67, further comprising designating, by a computing device, a wall cavity access location in a first area of the at least one wall having a shear load requirement below a threshold level of shear load.

Clause 72. The method of clause 1, further comprising designating, by the optimization computing device, at least one of a cavity access location for the at least one structural component and a header assembly configuration for a cavity access location based on structural load requirements for the at least one structural component.

Clause 73. The system of clause 13, wherein the instructions, in response to execution by the at least one processor, cause the computing device to perform actions further comprising: designating, by the optimization computing device, at least one of a cavity access location for the at least one structural component and a header assembly configuration for a cavity access location based on structural load requirements for the at least one structural component.

Clause 74. The method of clause 25, further comprising training, by the optimization computing device, a machine learning model that processes a load capacity requirement of at least one structural component as input to designate at least one of a cavity access location and a header assembly configuration for a cavity access location for the at least one structural component as output.

Clause 75. The method of clause 36, further comprising using the machine learning model to designate at least one of a cavity access location and a header assembly configuration for a cavity access location for the at least one structural component as output using a load capacity requirement of at least one structural component as input.

Clause 76. The method of clause 52, further comprising designating, by the optimization computing device, at least one of a cavity access location for the at least one structural component and a header assembly configuration for a cavity access location based on structural load requirements for the at least one structural component.

What is claimed is:

1. A method for optimizing industrialized construction capacities of a building structure, comprising:
receiving, by at least one of a design computing device and an optimization computing device, framing design input information including at least one parameter for at least one structural component;
processing, by at least one of the design computing device and the optimization computing device, the framing design input information to identify the at least one parameter; and
designating, by the optimization computing device, at least one type of material for the at least one structural component based on a correlation between at least one property of the type of material and the at least one parameter of the at least one structural component.

2. The method of claim 1, further comprising designating at least one type of material for a first structural component based on a correlation between at least one property of the type of material and at least one parameter of the first structural component and designating at least one type of material for a second structural component based on a correlation between at least one property of the type of material and at least one parameter of the second structural component.

3. The method of claim 2, wherein the at least one parameter of the first structural component is a first load capacity and the at least one parameter of the second structural component is a second load capacity is lower than the first load capacity.

4. The method of claim 3, wherein the at least one type of material designated for the first structural component has a stiffness or other mechanical property greater than the at least one type of material designated for the second structural component.

5. The method of claim 3, wherein the at least one type of material designated for the first structural component has an embodied carbon lower than the at least one type of material designated for the second structural component.

6. The method of claim 1, further comprising at least one of custom fabricating, by a fabrication computing system, the at least one type of material to define the at least one structural component of the at least one type of material and adding at least one indicia to the at least one structural component of the at least one type of material to indicate at least one of a type of material name, an optimization rating, and installation instructions.

7. The method of claim 1, further comprising providing a visual browser interface showing a position of the at least one structural component of the at least one type of material relative to at least one other structural component of the building structure.

8. The method of claim 1, further comprising designating, by the optimization computing device, at least one of a cavity access location for the at least one structural component and a header assembly configuration for a cavity access location based on structural load requirements for the at least one structural component.

9. The method of claim 1, wherein the at least one parameter of the at least one structural component includes at least one of load capacity requirements, building code requirements, building use, building type, structural layout, a location of the structural member within a building structure, thermal resistance objectives, thermal performance requirements, embodied carbon/energy requirements, carbon sink requirements, cost requirements, cavity access location requirements, and MEPI requirements.

10. A method of using a machine learning model to optimize industrialized construction capacities of a building structure, the method comprising:
receiving, by a computing device, framing design input information including at least one parameter for at least one structural component of a building structure;
processing, by the computing device, the at least one parameter as input using a machine learning model to designate at least one type of material for the at least one structural component; and
presenting, by the computing device, at least one type of material for the at least one structural component.

11. The method of claim 10, wherein processing, by the computing device, the at least one parameter as input using a machine learning model to designate at least one type of material for the at least one structural component as output is based on a correlation between at least one property of the type of material and the at least one parameter of the structural component.

12. The method of claim 10, further comprising processing, by the computing device, at least one structural component dimension as input using the machine learning model to designate at least one of a load capacity and an environmental capacity for at least one type of material having the structural component dimensions as output.

13. The method of claim 10, further comprising processing, by the computing device, a correlation between at least one property of a type of material and at least one parameter of a first structural component and a correlation between at least one property of the type of material and at least one parameter of a second structural component as input using the machine learning model to designate at least one type of material for the second structural component as output.

14. The method of claim 10, further comprising processing, by the computing device, an overall load capacity requirement of at least a portion of a building structure as input using a machine learning model to designate at least one type of material for at least one of the structural components of a building structure as output.

15. The method of claim 10, further comprising processing, by the computing device, a location of first and second structural components the building structure as input, where the first structural component is located in a first location of the building structure, and the second structural component is located in a second location of the building structure, and using a machine learning model to designate at least one type of material for the first and second structural components as output.

16. The method of claim 10, further comprising processing, by the computing device at least one of structural component dimension, location, and load requirement as input, and using the machine learning model to designate at least one of a load capacity and an environmental capacity for at least one type of material having the structural component dimensions, location, or load requirements as output.

17. The method of claim 10, further comprising using the machine learning model to designate at least one of a cavity access location and a header assembly configuration for a cavity access location for the at least one structural component as output using a load capacity requirement of at least one structural component as input.

18. A method for optimizing industrialized construction capacities of a building structure, comprising:
receiving, by at least one of a design computing device and an optimization computing device, framing design input information including at least one parameter for at least one structural component;
processing, by at least one of the design computing device and the optimization computing device, the framing design input information to identify the at least one parameter; and
designating, by the optimization computing device, at least one type of material for the at least one structural component based on a correlation between at least one property of the type of material and the at least one parameter of the at least one structural component;
custom fabricating, by a fabrication computing system, the at least one type of material to define the at least one structural component of the at least one type of material; and
adding at least one indicia to the at least one structural component of the at least one type of material to indicate at least one of a type of material name, an optimization rating, and installation instructions.

19. The method of claim 18, further comprising designating by the optimization computing device, at least one type of material for a first structural component based on a correlation between at least one property of the type of material and at least one parameter of the first structural component and designating at least one type of material for a second structural component based on a correlation between at least one property of the type of material and at least one parameter of the second structural component.

20. The method of claim 19, wherein the at least one parameter of the first structural component is a first load capacity and the at least one parameter of the second structural component is a second load capacity is lower than the first load capacity.
